(19) United States
(12) Patent Application Publication
(10) Pub. No.: US 2026/0033022 A1
(43) Pub. Date: Jan. 29, 2026

(54) SINGLE PHOTON DETECTION DEVICE AND ELECTRONIC DEVICE COMPRISING DIFFRACTION PATTERN

(71) Applicant: TRUPIXEL INC., Daejeon (KR)

(72) Inventor: Myung-Jae LEE, Daejeon (KR)

(21) Appl. No.: 19/281,111

(22) Filed: Jul. 25, 2025

(30) Foreign Application Priority Data
Jul. 25, 2024 (KR) 10-2024-0098999

(51) Int. Cl. H10F 30/225; G01S 7/481; G01S 17/10; G01S 17/931; H10F 30/221; H10F 77/40

(52) U.S. Cl. CPC H10F 30/225; G01S 7/4816; G01S 17/10; H10F 30/221; H10F 77/413; G01S 17/931

(57) ABSTRACT

Disclosed is a single photon detection device comprises a photodetection layer including a first surface and a second surface positioned opposite to each other. The photodetection layer comprises a first well having a first conductivity type, diffraction patterns positioned between the second surface and the first well, the diffraction patterns configured to receive incident light and diffract the incident light such that first-order diffracted light has a highest diffraction efficiency in a red or near-infrared wavelength band; a highly doped region positioned between the first surface and the first well and having a second conductivity type different from the first conductivity type, and a contact region electrically connected to the first well and having the first conductivity type.

### CROSS-REFERENCE TO RELATED APPLICATION

The application claims benefit of priority under 35 U.S.C. § 119 to Korean Patent Application No. 10-2024-0098999, filed on Jul. 25, 2024, in the Korean Intellectual Property Office, the disclosures of which are incorporated by reference herein in their entireties.

### BACKGROUND

The present disclosure relates generally to a single photon detection device and an electronic device.

An avalanche photodiode (APD) is a solid-state photodetector in which a high bias voltage is applied to a p-n junction to provide high gain due to avalanche multiplication. When an incident photon having energy greater than the bandgap of the semiconductor reaches the photodiode, an electron-hole pair (EHP) is generated. The high electric field rapidly accelerates photo-generated electrons toward the positive side, and additional electron-hole pairs are successively generated by impact ionization caused by the accelerated electrons, and then all of these electrons are accelerated toward the anode. Similarly, holes are rapidly accelerated toward the negative side and cause the same phenomenon. This process repeats the process leading to avalanche multiplication of photo-generated electrons or holes. Therefore, an APD is a semiconductor-based device that operates similarly to photomultiplier tubes. A linear mode APD is an effective amplifier that can set gain by controlling bias voltage and obtain gains of tens to thousands in linear mode.

A single-photon avalanche diode (SPAD) is an APD in which the p-n junction is biased above its breakdown voltage to operate in Geiger mode, where a single incident photon can trigger an avalanche phenomenon and generate a very large current, thereby obtaining an easily measurable pulse together with a quenching resistor or circuit. That is, a SPAD operates as a device that generates large pulses compared to linear mode APDs. After triggering an avalanche, a quenching resistor or circuit is used to reduce the bias voltage below the breakdown voltage to quench the avalanche process. Once quenched, the bias voltage is raised again above the breakdown voltage so that the SPAD is reset for detection of another photon.

A SPAD can be configured together with a quenching resistor or circuit as well as a recharge circuit, memory, gate circuit, counter, time-to-digital converter, and the like. Since SPAD pixels are semiconductor-based, they can be easily configured as arrays.

### SUMMARY

One or more example embodiments may provide a single photon detection device and an electronic device having improved light absorption efficiency.

According to an embodiment, a single photon detection device may comprise a photodetection layer including a first surface and a second surface positioned opposite to each other. The photodetection layer may comprise a first well having a first conductivity type, diffraction patterns positioned between the second surface and the first well, the diffraction patterns configured to receive incident light and diffract the incident light such that first-order diffracted light has a highest diffraction efficiency in a red or near-infrared wavelength band, a highly doped region positioned between the first surface and the first well and having a second conductivity type different from the first conductivity type, and a contact region electrically connected to the first well and having the first conductivity type.

In some embodiments, the diffraction patterns may be arranged to have a pitch of 0.4 micrometers (μm) to 0.7 micrometers (μm).

In some embodiments, the diffraction patterns may be exposed on the second surface and contact the first well.

In some embodiments, the diffraction patterns may contact the first well.

In some embodiments, the diffraction patterns may have a + shape, an x shape, and a shape in which + and x are overlapped.

In some embodiments, the photodetection layer may further comprise a guard ring provided between the highly doped region and the contact region, having the second conductivity type, and having a doping concentration lower than the highly doped region.

In some embodiments, the photodetection layer may further comprise a relaxation region provided on the contact region, having the first conductivity type, and having a doping concentration lower than the contact region.

In some embodiments, the photodetection layer may further comprise a lightly doped region provided on the highly doped region.

In some embodiments, the lightly doped region may cover side surfaces and a top surface of the highly doped region.

In some embodiments, the single photon detection device may further comprise a connection layer provided on the first surface. The connection layer may comprise an output pattern electrically connected to the highly doped region; a bias pattern electrically connected to the contact region; and vertical connection parts provided between the output pattern and the highly doped region and between the bias pattern and the contact region.

In some embodiments, the output pattern may have a width wider than the highly doped region.

In some embodiments, the photodetection layer may further comprise a second well provided between the highly doped region and the first well and having the first conductivity type.

In some embodiments, the single photon detection device may further comprise a third well provided between the highly doped region and the first well, having the second conductivity type, and having a doping concentration lower than the highly doped region.

In some embodiments, the photodetection layer may further comprise a device isolation pattern surrounding the contact region and a vertical isolation pattern provided between the device isolation pattern and the second surface.

According to another embodiment, an electronic device may comprise a light emission device and a single photon detection device for detecting incident light that is emitted from the light emission device, reflected by a subject, and returned, the electronic device being configured to measure a distance to the subject using time difference information between a transmission signal of the light emission device and a detection signal of the single photon detection device. The single photon detection device may comprise a photodetection layer including a first surface and a second surface positioned opposite to each other. The photodetection layer may comprise a first well having a first conductivity type, diffraction patterns positioned between the second surface and the first well and configured to receive incident light and diffract the incident light such that first-order diffracted light has a highest diffraction efficiency in a red or near-infrared wavelength band, a highly doped region positioned between the first surface and the first well and having a second conductivity type different from the first conductivity type, and a contact region electrically connected to the first well and having the first conductivity type.

In some embodiments, the diffraction patterns may be arranged to have a pitch of 0.4 micrometers (μm) to 0.7 micrometers (μm).

In some embodiments, the diffraction patterns may be exposed on the second surface and contact the first well.

In some embodiments, the single photon detection device may further comprise a connection layer provided on the first surface. The connection layer may comprise an output pattern electrically connected to the highly doped region, a bias pattern electrically connected to the contact region, and vertical connection parts provided between the output pattern and the highly doped region and between the bias pattern and the contact region.

In some embodiments, the output pattern may have a width wider than the highly doped region.

In some embodiments, the photodetection layer may further comprise a device isolation pattern surrounding the contact region, and a vertical isolation pattern provided between the device isolation pattern and the second surface.

Additional aspects will be set forth in part in the description which follows and, in part, will be apparent from the description, or may be learned by practice of the presented embodiments.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a plan view of a single photon detection device according to an exemplary embodiment.

FIG. 2 is a cross-sectional view taken along line A-A′ of FIG. 1.

FIGS. 3A, 3B, 3C, 3D, 3E, 3F, 3G, and 3H are plan views showing diffraction patterns of FIG. 1.

FIG. 4 is a cross-sectional view corresponding to line A-A′ of FIG. 1 for explaining an exemplary path of incident light.

FIG. 5A is a graph showing diffraction efficiency according to pitch of the diffraction patterns of the single photon detection device of FIG. 1.

FIG. 5B is a graph showing photon detection probability according to pitch of the diffraction patterns of the single photon detection device of FIG. 1.

FIGS. 6A, 6B, 6C, 6D, 6E, and 6F are plan views corresponding to FIG. 1 for explaining exemplary planar shapes of the single photon detection device described with reference to FIG. 2.

FIG. 7 is a plan view of a single photon detection device according to an exemplary embodiment.

FIG. 8 is a cross-sectional view taken along line B-B′ of the single photon detection device of FIG. 7.

FIGS. 9, 10, 11, 12, 13, 14, 15, 16, 17 and 18 are cross-sectional views corresponding to line B-B′ of FIG. 7.

FIG. 19 is a plan view of a single photon detection device according to an exemplary embodiment.

FIG. 20 is a cross-sectional view taken along line C-C′ of FIG. 19.

FIG. 21 is a plan view of a single photon detection device according to an exemplary embodiment.

FIG. 22 is a cross-sectional view taken along line D-D′ of FIG. 21.

FIG. 23 is a plan view of a single photon detection device according to an exemplary embodiment.

FIG. 24 is a cross-sectional view taken along line E-E′ of FIG. 23.

FIG. 25 is a plan view of a single photon detection device according to an exemplary embodiment.

FIG. 26 is a cross-sectional view taken along line F-F of FIG. 25.

FIGS. 27 and 28 are cross-sectional views corresponding to line A-A′ of FIG. 1.

FIG. 29 is a plan view of a single photon detection device array according to an exemplary embodiment.

FIG. 30 is a cross-sectional view taken along line G-G′ of FIG. 29.

FIG. 31 is a cross-sectional view taken along line G-G′ of FIG. 29.

FIG. 32 is a block diagram for explaining an electronic device according to an exemplary embodiment.

FIGS. 33 and 34 are conceptual diagrams showing a case where a LiDAR device according to an exemplary embodiment is applied to a vehicle.

### DETAILED DESCRIPTION

Hereinafter, example embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be also understood that, even if a certain step or operation of manufacturing an apparatus or structure is described later than another step or operation, the step or operation may be performed later than the other step or operation unless the other step or operation is described as being performed after the step or operation.

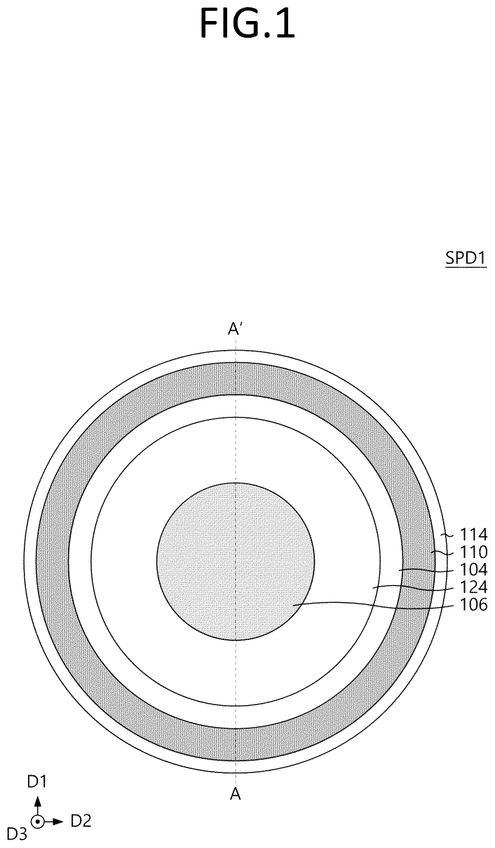

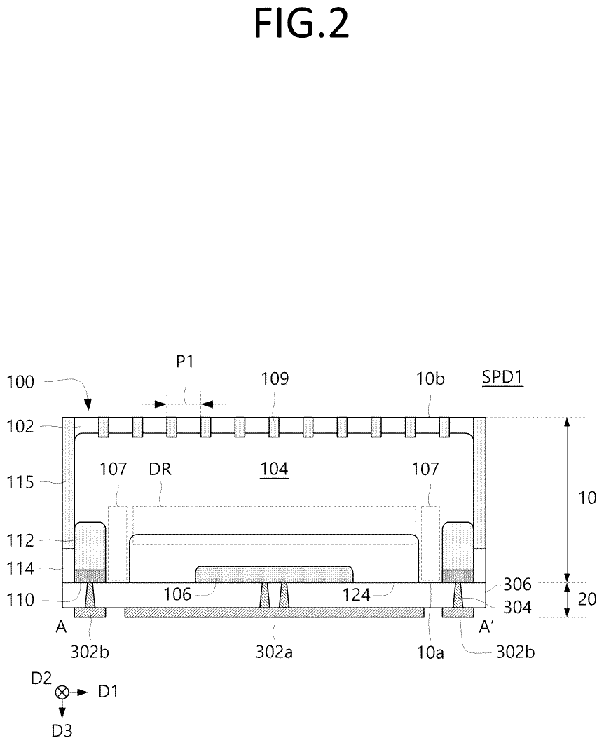

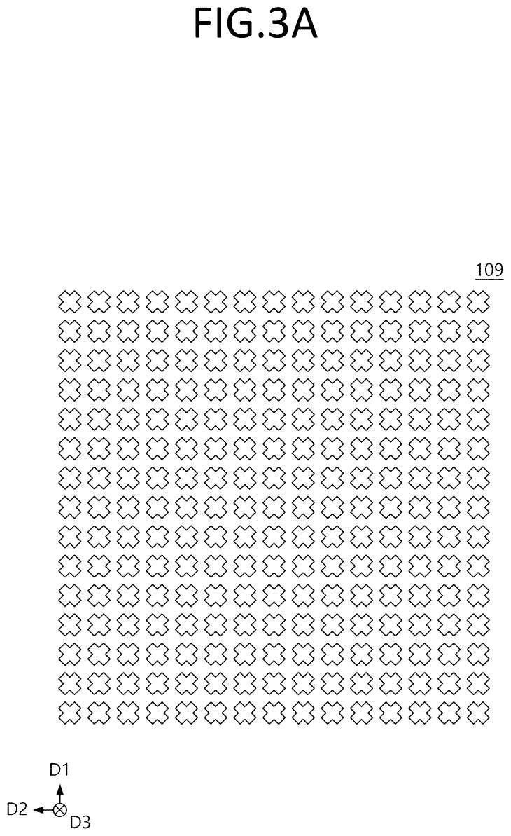

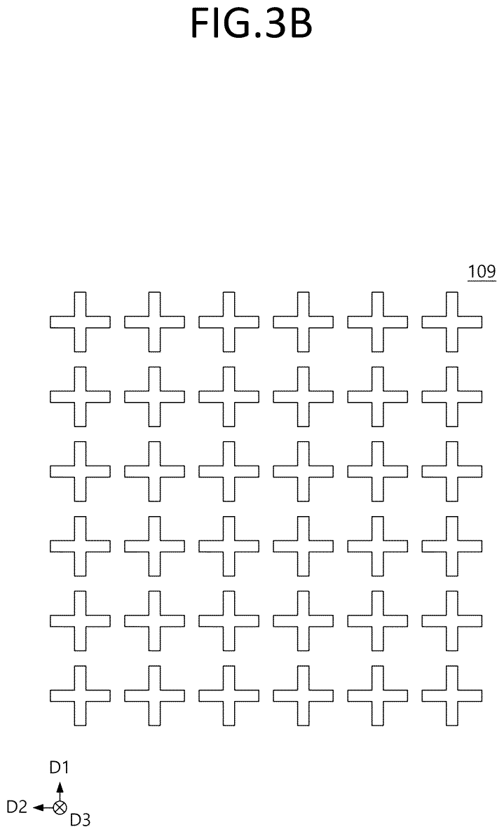

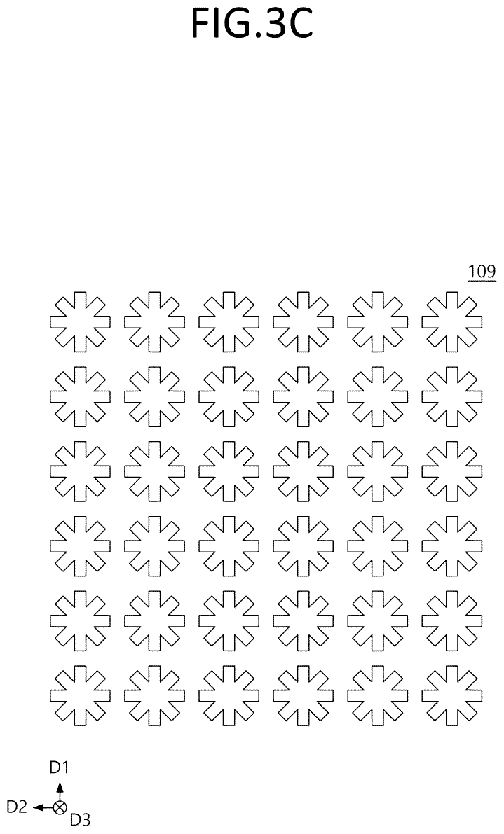

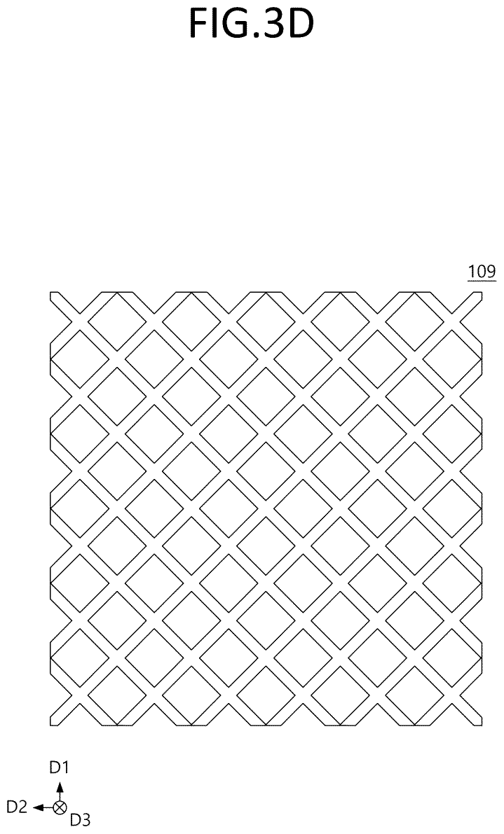

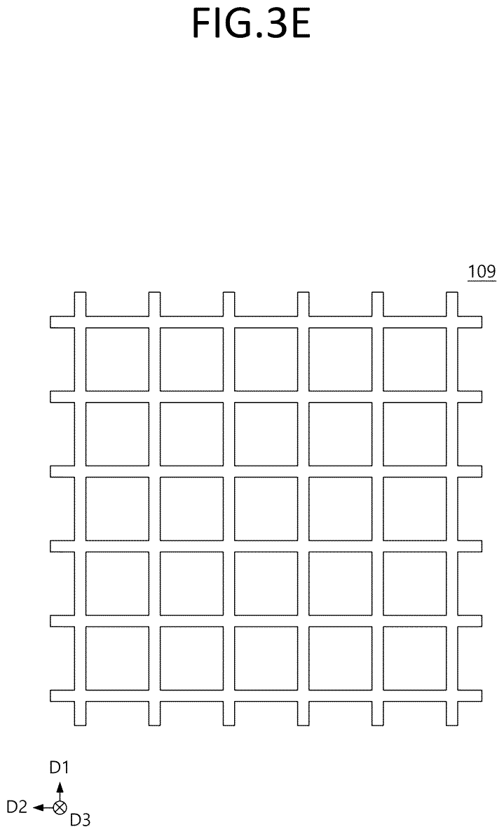

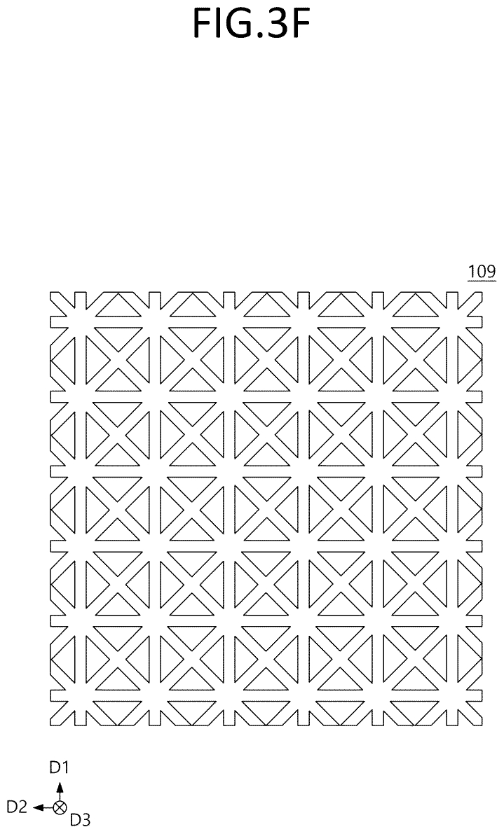

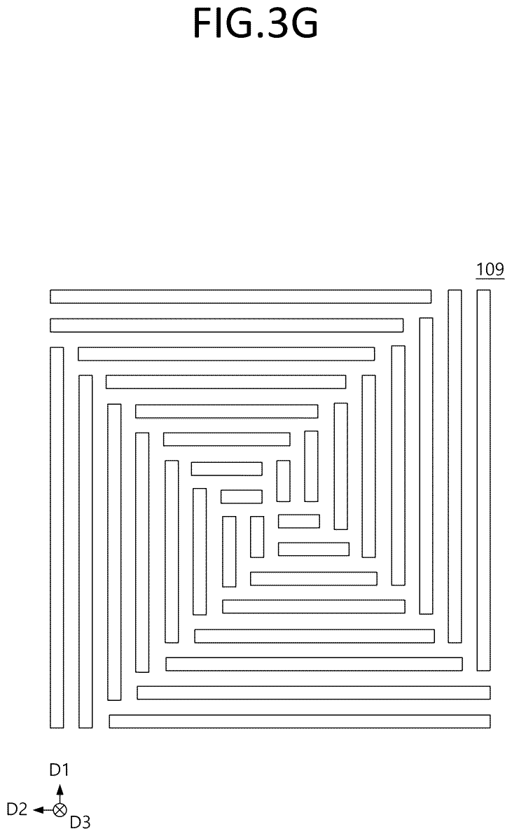

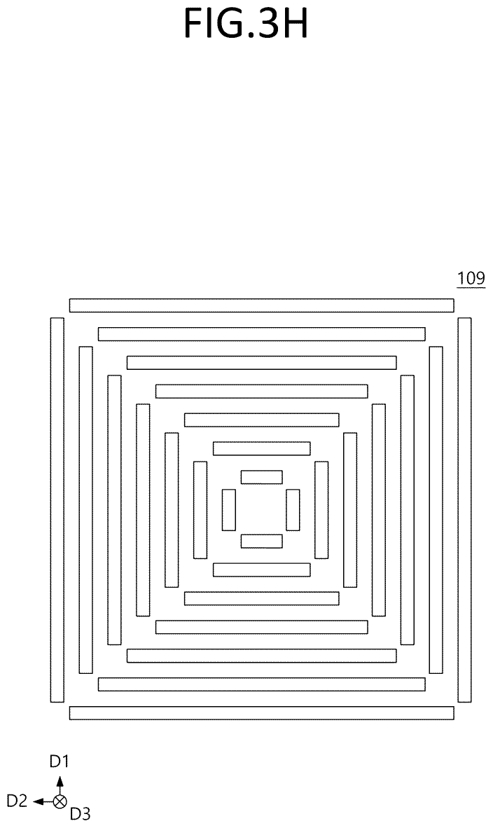

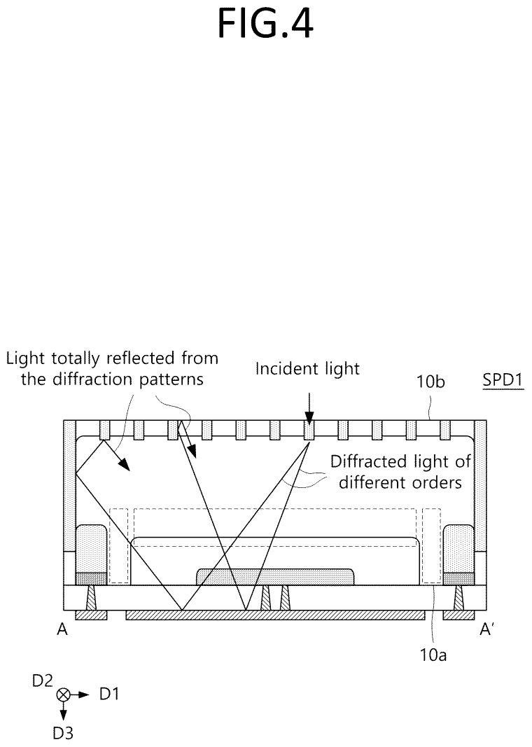

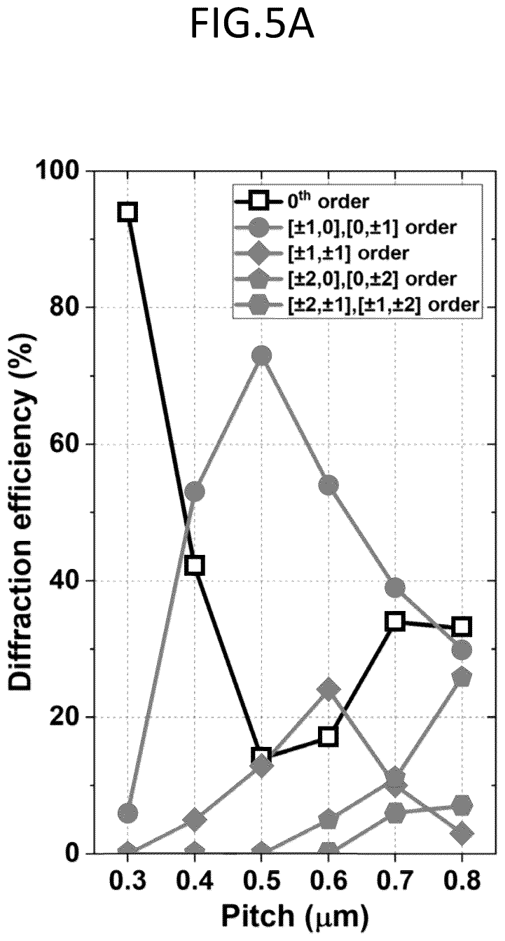

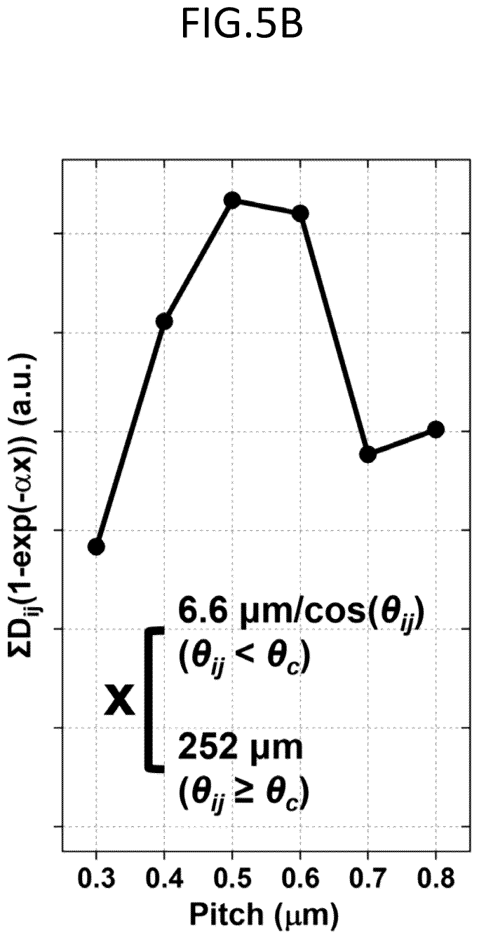

FIG. 1 is a plan view of a single photon detection device according to an exemplary embodiment. FIG. 2 is a cross-sectional view taken along line A-A′ of FIG. 1. FIGS. 3A through 3H are plan views showing diffraction patterns of FIG. 1. FIG. 4 is a cross-sectional view corresponding to line A-A′ of FIG. 1 for explaining an exemplary path of incident light. FIG. 5A is a graph showing diffraction efficiency according to pitch of the diffraction patterns of the single photon detection device of FIG. 1. FIG. 5B is a graph showing photon detection probability according to pitch of the diffraction patterns of the single photon detection device of FIG. 1.

Referring to FIGS. 1 through 3, a single photon detection device SPD1 may be provided. The single photon detection device SPD1 may include a photodetection layer 10 and a connection layer 20. The photodetection layer 10 may include a front surface (frontside) 10a and a back surface (backside) 10b opposing each other. The front surface 10a may be a surface on which various semiconductor processes are performed during manufacturing of the photodetection layer 10, and the back surface 10b may be a surface disposed on the opposite side of the front surface. The front surface 10a and the back surface 10b may extend along a first direction D1 and a second direction D2. A direction from the back surface 10b toward the front surface 10a may be a third direction D3. The photodetection layer 10 may include a first well 104, a second well 124, a highly doped region 106, a contact region 110, a relaxation region 112, a device isolation pattern 114, a vertical isolation pattern 115, and diffraction patterns 109 formed in a semiconductor substrate 100. On the front surface 10a, the highly doped region 106 may have a circular shape, and the second well 124, the first well 104, the contact region 110, and the device isolation pattern 114 may have a circular ring shape surrounding the highly doped region 106. The semiconductor substrate 100 may be an epi layer formed by an epitaxial growth process. For example, the semiconductor substrate 100 may be a silicon substrate. For example, the first well 104, the second well 124, the highly doped region 106, the contact region 110, and the relaxation region 112 may be formed by implanting impurities into the semiconductor substrate 100. The remaining region of the semiconductor substrate 100 excluding the first well 104, the second well 124, the highly doped region 106, the contact region 110, and the relaxation region 112 may be referred to as a substrate region 102.

The conductivity type of the substrate region 102 may be n-type or p-type. When the conductivity type of the substrate region 102 is n-type, it may include Group V elements (e.g., phosphorus (P), arsenic (As), antimony (Sb), and the like), Group VI, or Group VII elements as impurities. Hereinafter, a region having n-type conductivity may include Group V, Group VI, or Group VII elements as impurities (hereinafter, first impurities). When the conductivity type of the substrate region 102 is p-type, the substrate region 102 may include Group III elements (e.g., boron (B), aluminum (Al), gallium (Ga), indium (In), and the like) or Group II elements as impurities. Hereinafter, a region having p-type conductivity may include Group III or Group II elements as impurities (hereinafter, second impurities). For example, the doping concentration of the substrate region 102 may be 1×10¹⁴ to 1×10¹⁹ cm⁻³. The semiconductor substrate may be an epi layer formed by an epitaxial growth process.

The first well 104 may be provided between the substrate region 102 and the connection layer 20. The first well 104 may directly contact the substrate region 102. The first well 104 may have a first conductivity type. For example, the doping concentration of the first well 104 may be 1×10¹⁵ to 1×10¹⁸ cm⁻³. In exemplary embodiments, the first well 104 may have a uniform doping concentration. In exemplary embodiments, the doping concentration of the first well 104 may become smaller as it gets closer to the front surface 10a. Although the bottom surface of the first well 104 is shown as being disposed at substantially the same level as the front surface 10a, this is not limiting. In another example, the bottom surface of the first well 104 and the front surface 10a may be spaced apart from each other along the third direction D3. The region between the bottom surface of the first well 104 and the front surface 10a may be the substrate region 102.

The highly doped region 106 may be provided between the first well 104 and the connection layer 20. The highly doped region 106 may have a second conductivity type different from the first conductivity type. When the first conductivity type is n-type or p-type, the second conductivity type may be p-type or n-type, respectively. For example, the doping concentration of the highly doped region 106 may be 1×10¹⁵ to 2×10²⁰ cm⁻³. The highly doped region 106 may be electrically connected to at least one of an external power source, a DC-to-DC converter, and other power management integrated circuits. In exemplary embodiments, the highly doped region 106 may be electrically connected to at least one of a quenching resistor (or quenching circuit) and other pixel circuits. The quenching resistor or quenching circuit may stop the avalanche effect and allow the photodetection layer 10 to detect another photon. The other pixel circuits may include, for example, a reset or recharge circuit, memory, an amplification circuit, a counter, a gate circuit, a time-to-digital converter, and the like. The other pixel circuits may transmit signals to the photodetection layer 10 or receive signals from the photodetection layer 10.

The second well 124 may be provided between the first well 104 and the highly doped region 108. The second well 124 may space the highly doped region 108 and the first well 104 apart from each other. The second well 124 may have a second conductivity type different from the first conductivity type. The doping concentration of the second well 124 may be lower than the doping concentration of the highly doped region 108. For example, the doping concentration of the second well 124 may be 1×10¹⁶ to 1×10¹⁸ cm⁻³.

As the second well 124 and the first well 104 have different conductivity types, a depletion region DR may be formed at and around the boundary between the second well 124 and the first well 104. The depletion region DR may be configured to multiply charges generated in the depletion region DR and charges transferred to the depletion region DR. For example, during operation of the single photon detection device SPD1, an electric field having a magnitude of 3×10⁵ V/cm or more may be applied to the depletion region DR. The depletion region DR may be referred to as a multiplication region.

As the doping concentration of the first well 104 becomes smaller as it gets closer to the front surface 10a, a virtual guard ring 107 may be formed between the second well 124 and the relaxation region 112. The virtual guard ring 107 may be part of the first well 104 or the substrate region 102. The virtual guard ring 107 may surround the second well 124. For example, the virtual guard ring 107 may have a ring shape extending along the region between the second well 124 and the relaxation region 112. The virtual guard ring 107 may prevent premature breakdown by relieving electric field concentration in a portion of the depletion region DR. The breakdown characteristics of the single photon detection device SPD1 may be improved by the virtual guard ring 107. Premature breakdown refers to breakdown occurring first in a portion of the depletion region DR before a sufficient electric field is applied throughout the depletion region DR, and occurs as the electric field concentrates in a portion of the depletion region DR. The depth of the guard ring 108 may be determined as needed. The depth of the guard ring 108 may refer to the distance between the front surface 10a and the top surface of the guard ring 108. For example, the guard ring 108 may be formed deeper or shallower than shown.

The contact region 110 may be provided on the side of the second well 124. The contact region 110 may be provided on the opposite side of the second well 124 with the virtual guard ring 107 therebetween. The contact region 110 may be exposed on the front surface 10a. On the front surface 10a, the contact region 110 may surround the second well 124. In another example, a plurality of contact regions 110 may be provided. In this case, the plurality of contact regions may be electrically connected to circuits outside the photodetection layer 10, respectively. The contact region 110 may have a first conductivity type. The doping concentration of the contact region 110 may be higher than the doping concentration of the first well 104. For example, the doping concentration of the contact region 110 may be 1×10¹⁵ to 2×10²⁰ cm⁻³. In exemplary embodiments, the contact region 110 may be electrically connected to at least one of an external power source, a DC-to-DC converter, and other power management integrated circuits. In exemplary embodiments, the contact region 110 may be electrically connected to at least one of a quenching resistor (or quenching circuit) and other pixel circuits.

The relaxation region 112 may be provided on the contact region 110. The relaxation region 112 may be provided between the contact region 110 and the first well 104. The relaxation region 112 may be electrically connected to the contact region 110 and the first well 104. The relaxation region 112 may improve the electrical connection characteristics between the contact region 110 and the first well 104. For example, the relaxation region 112 may be configured to reduce or prevent voltage drop when voltage is applied to the first well 104 through the contact region 110, and to allow voltage to be uniformly applied to the first well 104. The relaxation region 112 may extend along the contact region 110. The relaxation region 112 may contact the top surface of the contact region 110. In other exemplary embodiments, the relaxation region 112 may contact the side surface and top surface of the contact region 110. The first well 104 may extend between the relaxation region 112 and the second well 124. The region between the relaxation region 112 and the second well 124 may be entirely filled with the first well 104. The first well 104 may be exposed on the front surface 10a between the relaxation region 112 and the second well 124. The relaxation region 112 may have a first conductivity type. The doping concentration of the relaxation region 112 may be lower than the doping concentration of the contact region 110 and similar to or higher than the doping concentration of the first well 104. For example, the doping concentration of the relaxation region 112 may be 1×10¹⁵ to 5×10¹⁷ cm⁻³.

Diffraction patterns 109 may be provided in a region adjacent to the back surface 10b. The diffraction patterns 109 may be exposed on the back surface 10b. For example, the top surfaces of the diffraction patterns 109 may be coplanar with the back surface 10b. The diffraction patterns 109 may be arranged along a direction parallel to the back surface 10b. For example, the diffraction patterns 109 may be arranged along the first direction D1 and the second direction D2. As shown in FIGS. 3A through 3H, the diffraction patterns 109 may have various shapes. From a vertical perspective, the diffraction patterns 109 are shown as having a rectangular shape, but this is exemplary. In other exemplary embodiments, from a vertical perspective, the diffraction patterns 109 may have various shapes such as cylindrical, conical, pyramidal, trapezoidal, and the like. The diffraction patterns 109 may diffract incident light to increase the absorption length of light within the substrate 100.

As shown in FIG. 4, when the diffraction patterns 109 have a rectangular shape from a vertical perspective, the diffraction patterns 109 may be configured to diffract incident light and, for light propagating inside the single photon detection device SPD1, totally reflect such light when the light reaches the diffraction patterns 109, thereby increasing the absorption length of light within the substrate 100. For example, light incident into the single photon detection device SPD1 through the back surface 10b may be reflected by an output pattern 302a or a bias pattern 302b described later and then incident on the diffraction patterns 109. The light reflected by the output pattern 302a or the bias pattern 302b may be directly incident on the diffraction patterns 109 or may be reflected by the vertical isolation pattern 115 and then incident on the diffraction patterns 109. In exemplary embodiments, the sidewall of the vertical isolation pattern 115 may be doped with a material having high reflectivity to form a side reflection layer. For example, the material having high reflectivity may be boron. The side reflection layer may be configured to reflect light incident on the side reflection layer.

The diffraction patterns 109 may extend from the back surface 10b along the third direction D3. For example, the diffraction patterns 109 may extend through the substrate region 102 to the first well 104. In other exemplary embodiments, the diffraction patterns 109 may be formed to be spaced apart from the first well 104. That is, the diffraction patterns 109 may extend to a position not in contact with the first well 104. The diffraction patterns 109 may include an electrically insulating material. For example, the diffraction patterns 109 may include silicon oxide (e.g., SiO₂), silicon nitride (e.g., SiN), silicon oxynitride (e.g., SiON), aluminum oxide (e.g., Al₂O₃), hafnium oxide (e.g., HfO₂), or combinations thereof. In exemplary embodiments, the diffraction patterns 109 may be formed by a process of filling grooves formed by performing an etching process on the back surface 10b with an electrically insulating material. The single photon detection device SPD1 has wavelength bands of light that are well absorbed according to substrate material characteristics, and the light absorption efficiency of the device can be improved by making the propagation length of light long within the single photon detection device SPD1 even for light in wavelength bands that are not well absorbed. For example, light having wavelengths in the blue (400-500 nm) or green (500-600 nm) regions is well absorbed in a silicon substrate and can be detected with high efficiency by the single photon detection device SPD1, but light having wavelengths in the red (600-750 nm) or near-infrared (750 nm-1 μm) regions is not well absorbed in a silicon substrate and may be difficult to detect. Therefore, the diffraction patterns 109 may be used to more effectively detect light in wavelength bands that are not well absorbed. This is because the diffraction patterns 109 can increase the light absorption efficiency by making the propagation length of light within the single photon detection device SPD1 long.

The diffraction patterns 109 may divide incident light from 0th order diffracted light to nth order diffracted light. The higher the order of diffracted light, the greater the diffraction angle may be. The 0th order diffracted light may be light output in the same direction as the incident direction of incident light. The 1st to nth order diffracted light may be diffracted light detected sequentially as it moves away from the 0th order diffracted light, which is centered perpendicular to the incident direction of light. When the 1st order diffracted light has relatively higher diffraction efficiency than other diffracted lights (0th order diffracted light, 2nd order diffracted light, and the like), the single photon detection device SPD1 may have high photon detection probability (PDP) or photon detection efficiency (PDE). Diffraction efficiency is calculated as the intensity of diffracted light relative to the intensity of total incident light, where the diffracted light can be measured by selecting a diffraction order.

By adjusting the pitch P1 between the diffraction patterns 109, the 1st order diffracted light can be determined to have higher diffraction efficiency than other diffracted lights. For example, for the single photon detection device SPD1 to effectively absorb light in the red or near-infrared wavelength bands, the pitch P1 between the diffraction patterns 109 may be 0.4 micrometers (μm) to 0.7 micrometers (μm). By adjusting the pitch P1 between the diffraction patterns 109 as described above, the single photon detection device SPD1 can be configured to effectively absorb near-infrared light in the 850 nm or 940 nm wavelength bands. Additionally, the diffraction patterns 109 do not affect the detection of light in wavelength bands that are well absorbed by the single photon detection device SPD1 in the substrate. For example, light having wavelengths in the blue (400-500 nm) or green (500-600 nm) regions in a silicon substrate can be detected by the single photon detection device SPD1 regardless of the presence of the diffraction patterns 109.

The device isolation pattern 114 may surround the relaxation region 112. The device isolation pattern 114 may be exposed on the front surface 10a. The device isolation pattern 114 may include an electrically insulating material. For example, the device isolation pattern 114 may include silicon oxide (e.g., SiO₂), silicon nitride (e.g., SiN), silicon oxynitride (e.g., SiON), or combinations thereof. The device isolation pattern 114 may be formed by, for example, a process of filling a recess region formed by etching the semiconductor substrate 100 with an electrically insulating material (e.g., silicon oxide). For example, the device isolation pattern 114 may be shallow trench isolation (STI). The device isolation pattern 114 may electrically isolate the photodetection layer 10 from other semiconductor devices (e.g., other photodetection layers 10 or electronic devices constituting other circuits (e.g., transistors)). Although the device isolation pattern 114 is shown as contacting the contact region 110 and the relaxation region 112, this is exemplary. In another example, the device isolation pattern 114 may be spaced apart from the contact region 110 and the relaxation region 112.

A vertical isolation pattern 115 may be provided between the device isolation pattern 114 and the back surface 10b. For example, the vertical isolation pattern 115 may be full trench isolation (FTI). The vertical isolation pattern 115 may directly contact the device isolation pattern 114 in a region adjacent to the front surface 10a. The vertical isolation pattern 115 may be exposed on the back surface 10b. For example, the top surface of the vertical isolation pattern 115 may be positioned at substantially the same level as the back surface 10b. The vertical isolation pattern 115 may surround the first well 104. The vertical isolation pattern 115 may be formed by a process of filling a recess region formed by etching the substrate region 102 with a material that prevents crosstalk between adjacent pixels PX. For example, the vertical isolation pattern 115 may include metal (e.g., copper (Cu), aluminum (Al), tungsten (W), titanium (Ti)), polysilicon, high-k material (e.g., hafnium oxide (HfO₂), zirconium oxide (zirconia, ZrO₂), tantalum oxide (TaO)), or combinations thereof. Although the vertical isolation pattern 115 is shown as contacting the device isolation pattern 114, this is exemplary. In another example, the vertical isolation pattern 115 may be spaced apart from the device isolation pattern 114. In another example, the vertical isolation pattern 115 may contact the front surface 10a.

The connection layer 20 may be provided on the front surface 10a. The connection layer 20 may include an insulating layer 306, an output pattern 302a and a bias pattern 302b, and a vertical connection part 304. For example, the insulating layer 306 may include silicon oxide (e.g., SiO₂), silicon nitride (e.g., SiN), silicon oxynitride (e.g., SiON), or combinations thereof. For example, the vertical connection part 304 may include a contact or a via.

The output pattern 302a may be electrically connected to the highly doped region 106 by the vertical connection part 304. The output pattern 302a may be configured to extract a detection signal from the photodetection layer 10. The output pattern 302a may include an electrically conductive material. For example, the output pattern 302a may include copper (Cu), aluminum (Al), tungsten (W), titanium (Ti), titanium nitride (TiN), or combinations thereof. The output pattern 302a and corresponding circuits may be electrically connected by conductive lines provided therebetween. The output pattern 302a may transmit the detection signal extracted from the photodetection layer 10 to corresponding circuits.

The bias pattern 302b may be electrically connected to the contact region 110 by the vertical connection part 304. The bias pattern 302b may be configured to apply a bias to the photodetection layer 10. The bias pattern 302b may include an electrically conductive material. For example, the bias pattern 302b may include copper (Cu), aluminum (Al), tungsten (W), titanium (Ti), titanium nitride (TiN), or combinations thereof. The bias pattern 302b and corresponding circuits may be electrically connected by conductive lines provided therebetween. The bias pattern 302b may be configured to apply a bias provided from corresponding circuits to the photodetection layer 10.

The output pattern 302a and the bias pattern 302b may function as a reflective layer. Light not absorbed in the photodetection layer 10 may be reflected by the output pattern 302a and the bias pattern 302b and incident again into the photodetection layer 10. Accordingly, the light absorption efficiency of the photodetection layer 10 may be improved. For this purpose, the output pattern may have a width wider than the highly doped region.

In exemplary embodiments, a shield pattern 302c may be provided between the output pattern 302a and the bias pattern 302b. The shield pattern 302c may electrically shield between the output pattern 302a and the bias pattern 302b. For example, the shield pattern 302c may be configured so that the detection signal extracted by the output pattern 302a is not affected by the bias signal applied to the bias pattern 302b. For example, the shield pattern 302c between the output pattern 302a and the bias pattern 302b may be electrically isolated from the output pattern 302a and the bias pattern 302b. For example, the shield pattern 302c may be spaced apart from the output pattern 302a and the bias pattern 302b.

Referring to FIG. 5A, the x-axis represents the pitch P1 of the diffraction patterns 109, and the y-axis represents the diffraction efficiency. “0th order” is a graph for 0th order diffracted light. “1st order” is a graph for 1st order diffracted light. “2nd order” is a graph for 2nd order diffracted light. For 940 nm near-infrared incident light, when the pitch P1 of the diffraction patterns 109 is 0.4 micrometers (μm) to 0.7 micrometers (μm), the diffraction efficiency of the 1st order diffracted light was higher than the diffraction efficiency of other order diffracted lights.

Referring to FIG. 5B, the x-axis represents the pitch P1 of the diffraction patterns 109, and the y-axis represents the sum of each diffraction efficiency×light propagation length within the single photon detection device SPD1, i.e., the expected efficiency. When the pitch P1 of the diffraction patterns 109 is 0.4 micrometers (μm) to 0.7 micrometers (μm), the expected efficiency for 940 nm near-infrared incident light within the single photon detection device SPD1 was relatively high.

The diffraction patterns 109 of the present disclosure can set the diffraction efficiency of 1st order diffracted light higher than the diffraction efficiency of other orders for near-infrared incident light by adjusting the pitch P1 thereof. Accordingly, a single photon detection device SPD1 with improved light absorption efficiency may be provided.

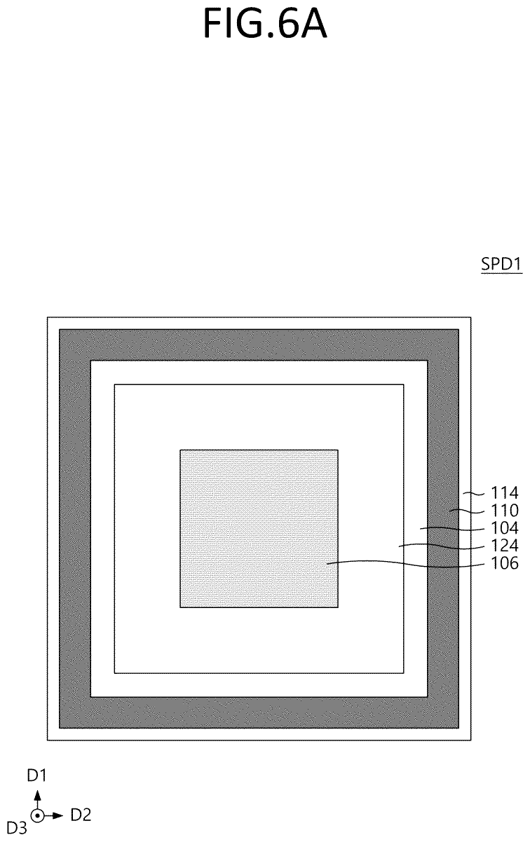

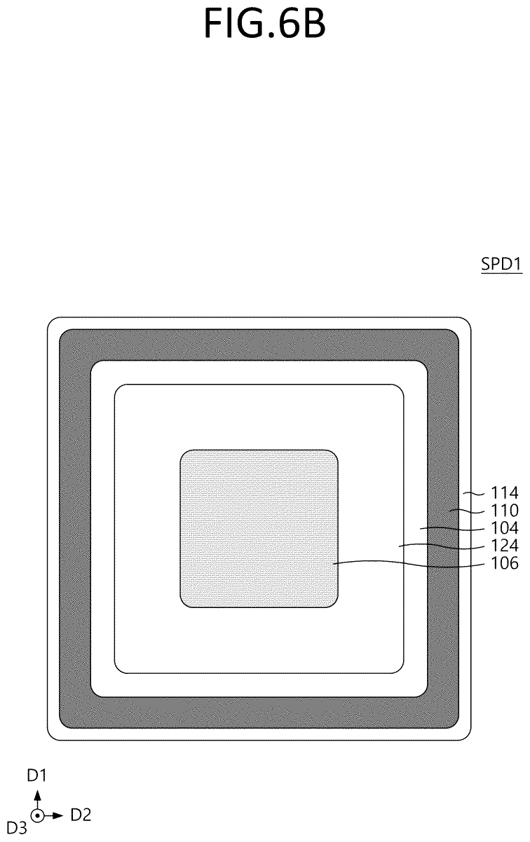

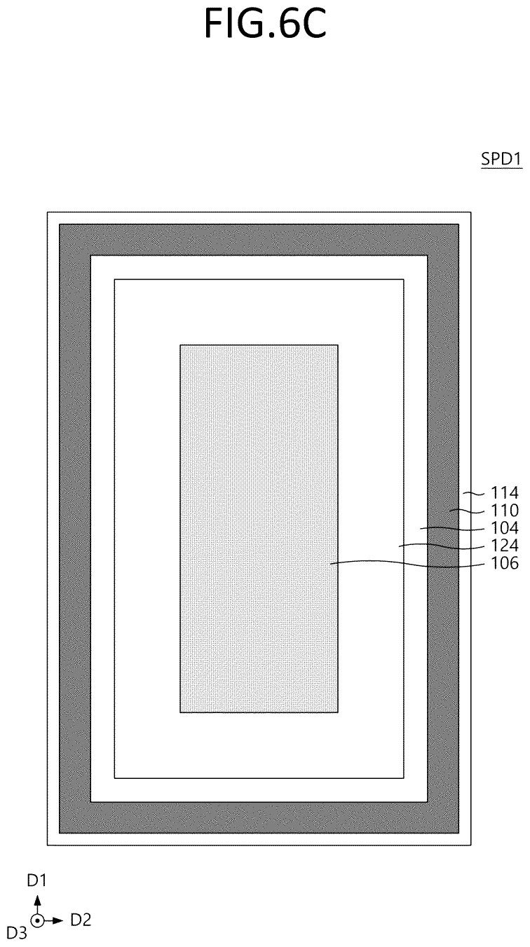

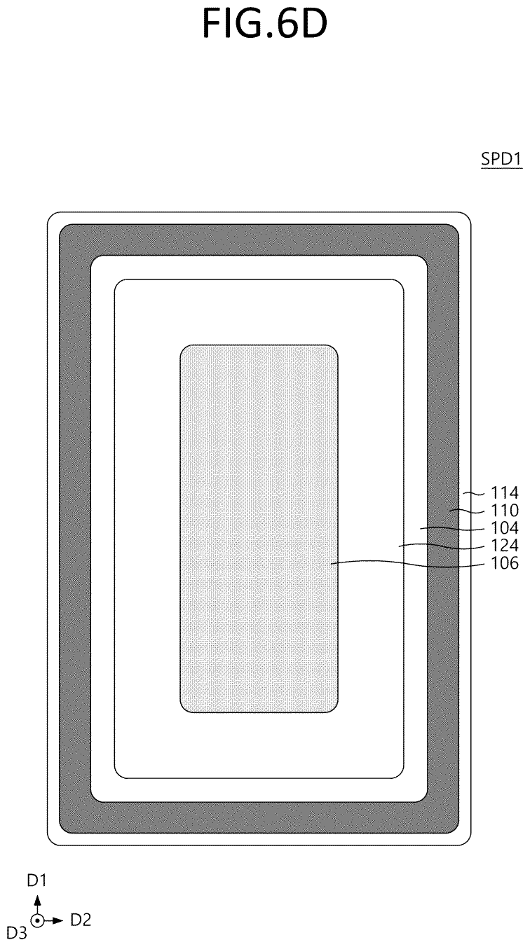

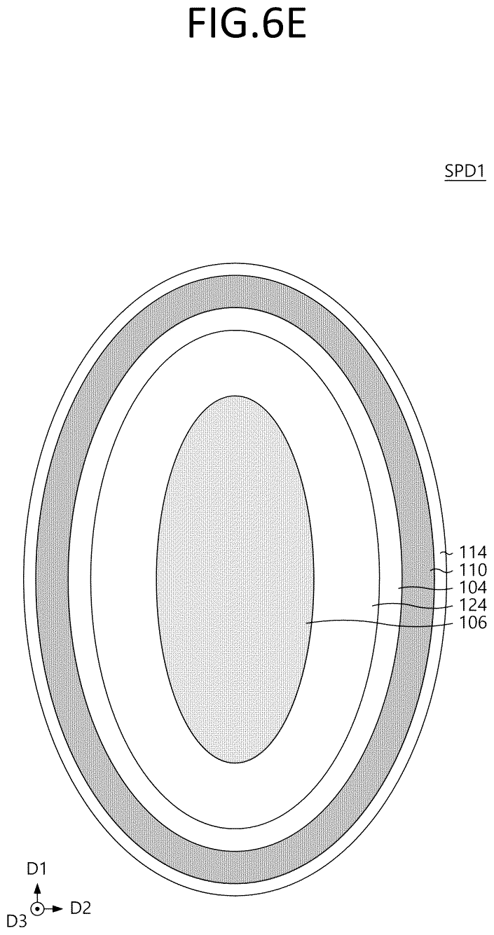

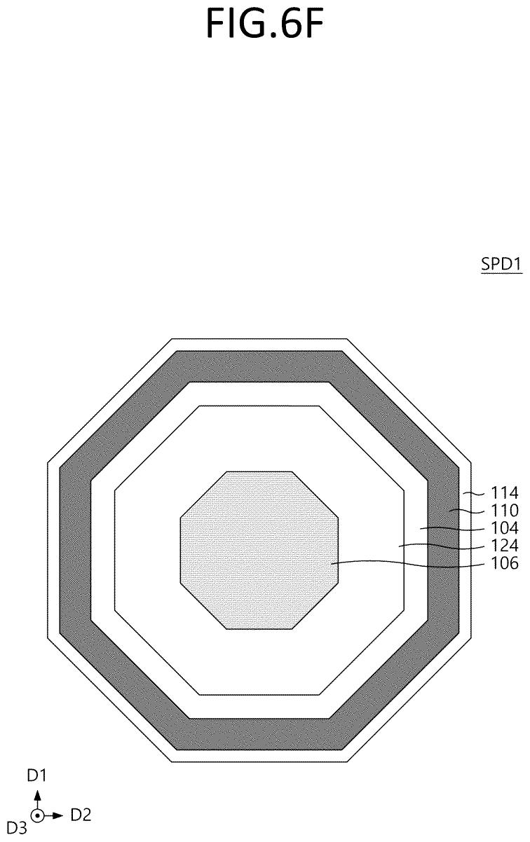

FIGS. 6A through 6F are plan views corresponding to FIG. 1 for explaining exemplary planar shapes of the single photon detection device described with reference to FIG. 2.

Referring to FIGS. 6A through 6F, a single photon detection device SPD1 may be provided. Unlike what is shown in FIG. 1, the highly doped region 106 may have a square shape, a square shape with rounded corners, a rectangular shape (excluding square shape), a rectangular shape with rounded corners (excluding square shape with rounded corners), an elliptical shape, or an octagonal shape, and the second well 124, the first well 104, the contact region 110, and the device isolation pattern 114 may have a square ring shape, a square ring shape with rounded corners, a rectangular ring shape (excluding square ring shape), a rectangular ring shape with rounded corners (excluding square ring shape with rounded corners), an elliptical ring shape, or an octagonal ring shape surrounding the highly doped region 106. The second well 124, the first well 104, the contact region 110, and the device isolation pattern 114 may be arranged in order in a direction away from the highly doped region 106. For example, the second well 124, the first well 104, the contact region 110, and the device isolation pattern 114 may have the same center.

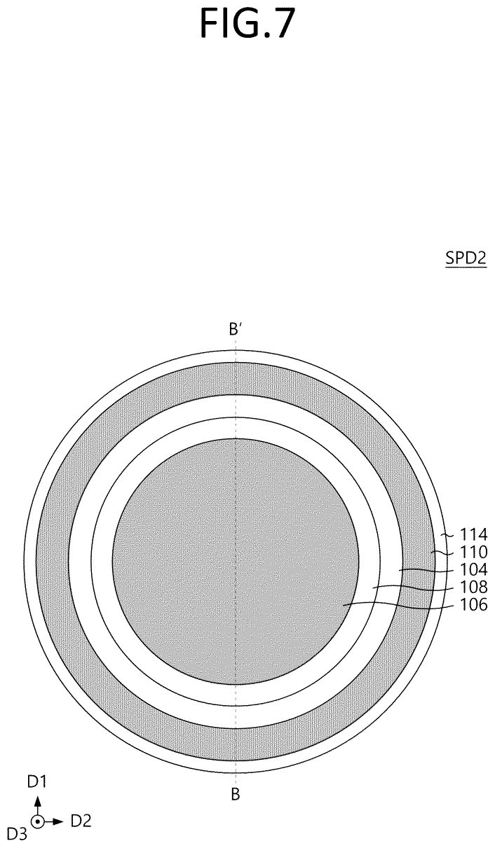

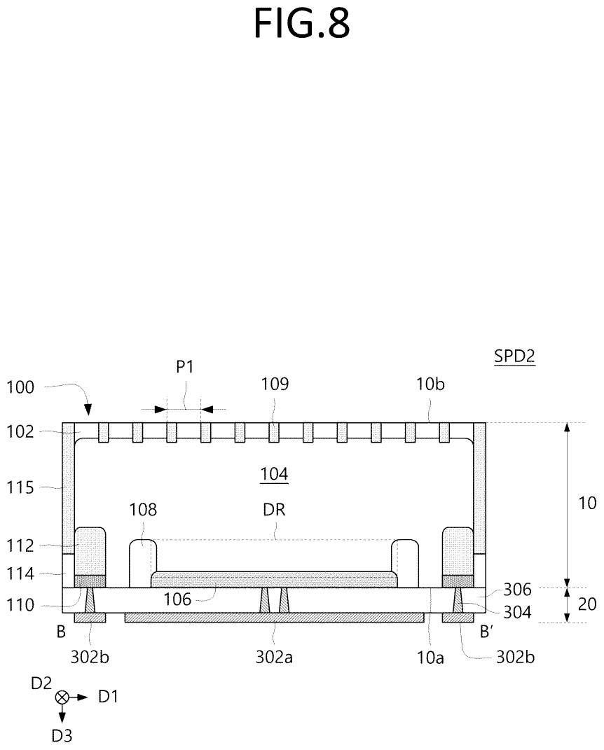

FIG. 7 is a plan view of a single photon detection device according to an exemplary embodiment. FIG. 8 is a cross-sectional view taken along line B-B′ of the single photon detection device of FIG. 7. For brevity of description, differences from what was described with reference to FIGS. 1 through 3 will be mainly described.

Referring to FIGS. 7 and 8, a single photon detection device SPD2 may be provided. Unlike what was described with reference to FIGS. 1 through 3, the single photon detection device SPD2 may not include the second well 124. The depletion region DR may be formed at and around the boundary between the highly doped region 106 and the first well 104.

Unlike what was described with reference to FIGS. 1 through 3, the single photon detection device SPD2 may include a guard ring 108. The guard ring 108 may surround the highly doped region 106. The guard ring 108 may be provided on the side surface of the highly doped region 106. For example, the guard ring 108 may have a ring shape extending along the side surface of the highly doped region 106. The guard ring 108 may directly contact the highly doped region 106. The guard ring 108 may be configured to surround the end of the highly doped region 106. For example, the guard ring 108 may contact the side surface and top surface of the end of the highly doped region 106. In exemplary embodiments, the guard ring 108 may be spaced apart from the highly doped region 106. The bottom surface of the guard ring 108 may be disposed at substantially the same level as the bottom surface of the highly doped region 106. The guard ring 108 may have a second conductivity type. The doping concentration of the guard ring 108 may be lower than the doping concentration of the highly doped region 108. For example, the doping concentration of the guard ring 108 may be 1×10¹⁵ to 1×10¹⁸ cm⁻³. The guard ring 108 may improve the breakdown characteristics of the single photon detector 10. Specifically, the guard ring 108 may prevent premature breakdown by relieving electric field concentration at the edge of the highly doped region 108. Premature breakdown refers to breakdown occurring first at the corner of the highly doped region 108 before a sufficient electric field is applied to the depletion region, and occurs as the electric field concentrates at the corner of the highly doped region 108. The depth of the guard ring 108 may be determined as needed. For example, the guard ring 108 may be formed deeper or shallower than shown.

The depletion region DR may be formed in a region surrounded by the guard ring 108. The region surrounded by the guard ring 108 may be a region on the inner side surface of the guard ring 108. The inner side surface of the guard ring 108 may be positioned opposite to the outer side surface of the guard ring 108. The outer side surface of the guard ring 108 may face the relaxation region 112 and the contact region 110.

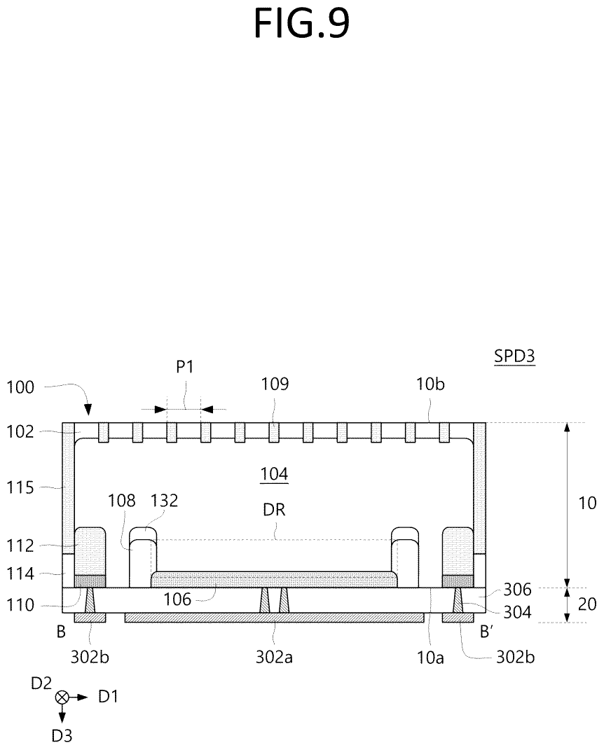

FIGS. 9 through 18 are cross-sectional views corresponding to line B-B′ of FIG. 7. For brevity of description, differences from what was described with reference to FIGS. 7 and 8 will be described.

Referring to FIG. 9, a single photon detection device SPD3 may be provided. Unlike what is shown in FIGS. 7 and 8, the single photon detection device SPD3 may include a first additional guard ring 132. The first additional guard ring 132 may be provided on the top surface of the guard ring 108. In exemplary embodiments, the side surface of the first additional guard ring 132 may be aligned with the side surface of the guard ring 108. For example, the side surface of the first additional guard ring 132 and the side surface of the guard ring 108 may be coplanar. The first additional guard ring 132 may have the same conductivity type as the guard ring 108 and the highly doped region 106. The first additional guard ring 132 may have a second conductivity type. For example, the doping concentration of the first additional guard ring 132 may be 1×10¹⁵ to 1×10¹⁸ cm⁻³. In exemplary embodiments, the first additional guard ring 132 may have a different doping concentration from the guard ring 108. The first additional guard ring 132 may reduce or prevent the occurrence of premature breakdown together with the guard ring 108.

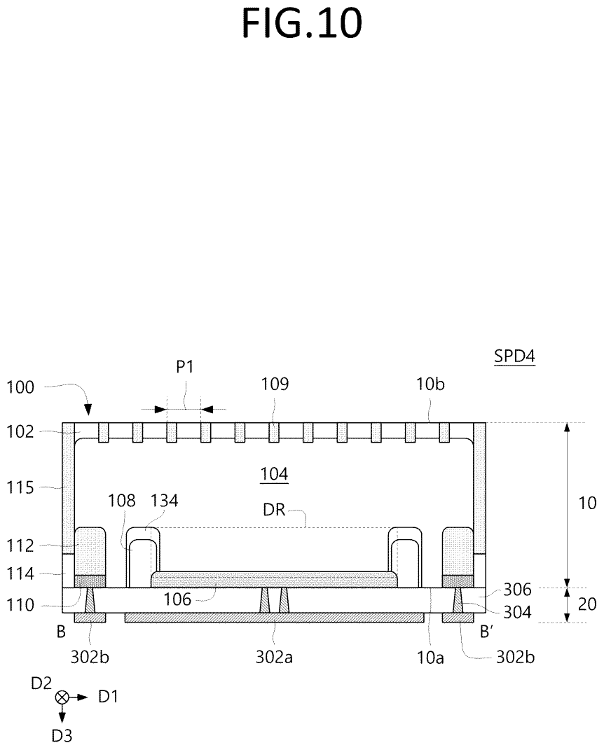

Referring to FIG. 10, a single photon detection device SPD4 may be provided. Unlike what is shown in FIGS. 7 and 8, the single photon detection device SPD4 may include a second additional guard ring 134. The second additional guard ring 134 may extend from a region on the top surface of the guard ring 108 to regions on the inner side surface and outer side surface of the guard ring 108. For example, the second additional guard ring 134 may cover the inner side surface and outer side surface of the guard ring 108. The guard ring 108 may be spaced apart from the first well 104 by the second additional guard ring 134. The second additional guard ring 134 may have the same conductivity type as the guard ring 108 and the highly doped region 106. The second additional guard ring 134 may have a second conductivity type. For example, the doping concentration of the second additional guard ring 134 may be 1×10¹⁵ to 1×10¹⁸ cm⁻³. In exemplary embodiments, the second additional guard ring 134 may have a different doping concentration from the guard ring 108. The second additional guard ring 134 may reduce or prevent the occurrence of premature breakdown together with the guard ring 108.

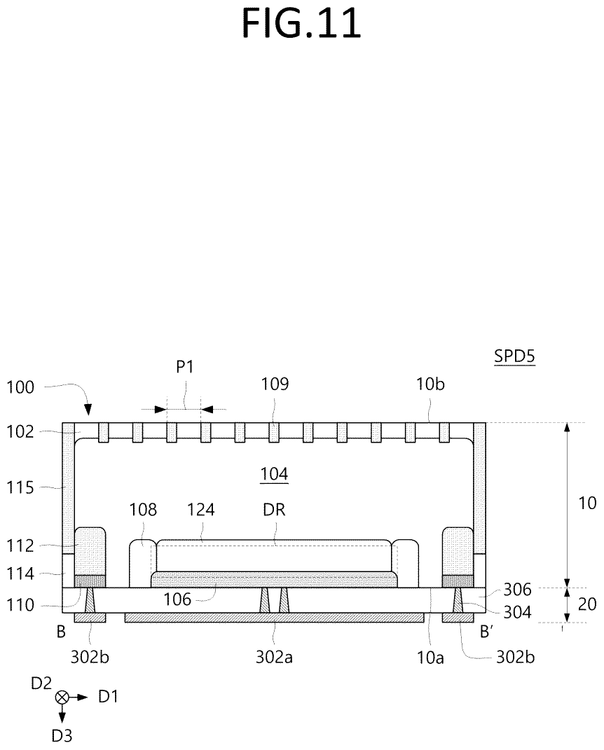

Referring to FIG. 11, a single photon detection device SPD5 may be provided. Unlike what is shown in FIGS. 7 and 8, the single photon detection device SPD5 may include the second well 124. The second well 124 may be provided between the first well 104 and the highly doped region 106. The second well 124 may space the first well 104 and the highly doped region 106 apart from each other. For example, the second well 124 may directly contact the first well 104 and the highly doped region 106. The second well 124 may be provided in an inner region of the guard ring 108 having a ring shape. From a perspective looking at the front surface 10a, the second well 124 may be surrounded by the guard ring 108. For example, the second well 124 may directly contact the guard ring 108. In exemplary embodiments, the second well 124 and the guard ring 108 may be formed to substantially the same depth. The depth may refer to the distance from the front surface 10a. For example, the top surface of the second well 124 and the top surface of the guard ring 108 may be positioned at substantially the same depth. The second well 124 may have a first conductivity type. For example, the doping concentration of the second well 124 may be 1×10¹⁵ to 5×10¹⁷ cm⁻³. In one example, the second well 124 may have a uniform doping concentration. In one example, the doping concentration of the second well 124 may become smaller as it gets closer to the highly doped region 106. However, the distribution of the doping concentration of the second well 124 may be determined as needed. For example, the doping concentration of the second well 124 may become larger as it gets closer to the highly doped region 106, or may become larger and then smaller as it gets closer to the highly doped region 106. The second well 124 may enhance the avalanche effect by increasing the electric field of the depletion region DR. The second well 124 may be configured to improve the characteristics of carriers (i.e., electrons or holes) moving from the first well 104 to the highly doped region 106.

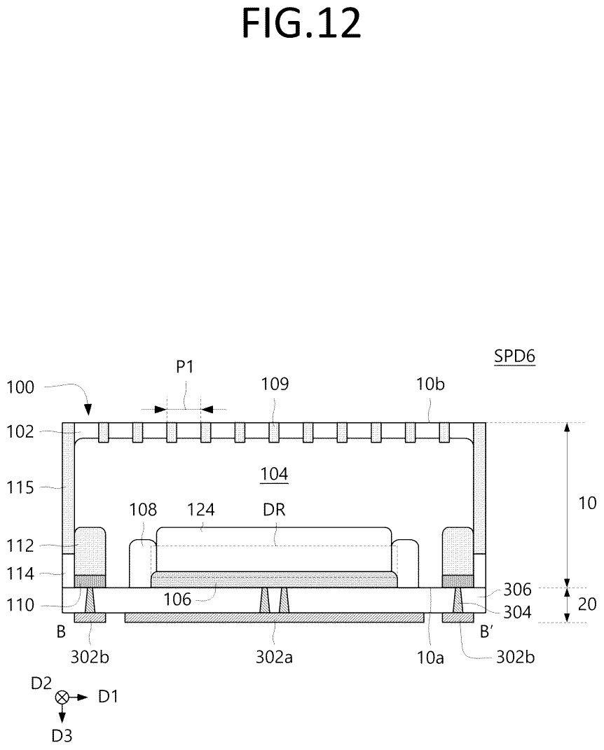

Referring to FIG. 12, a single photon detection device SPD6 may be provided. Unlike what is shown in FIG. 11, the guard ring 108 may extend to a depth shallower than the top surface of the second well 124. The top surface of the guard ring 108 may be positioned at a depth between the top surface of the second well 124 and the bottom surface of the second well 124.

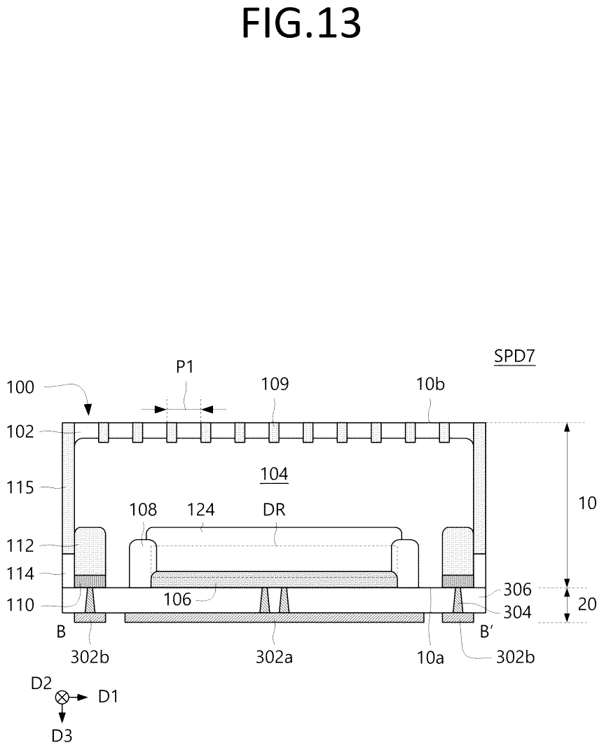

Referring to FIG. 13, a single photon detection device SPD7 may be provided. Unlike what is shown in FIG. 12, the second well 124 may extend from a region on the inner side surface of the guard ring 108 to a region on the top surface of the guard ring 108. For example, the second well 124 may cover the edge portion of the top surface of the guard ring 108. The second well 124 may contact the top surface of the guard ring 108.

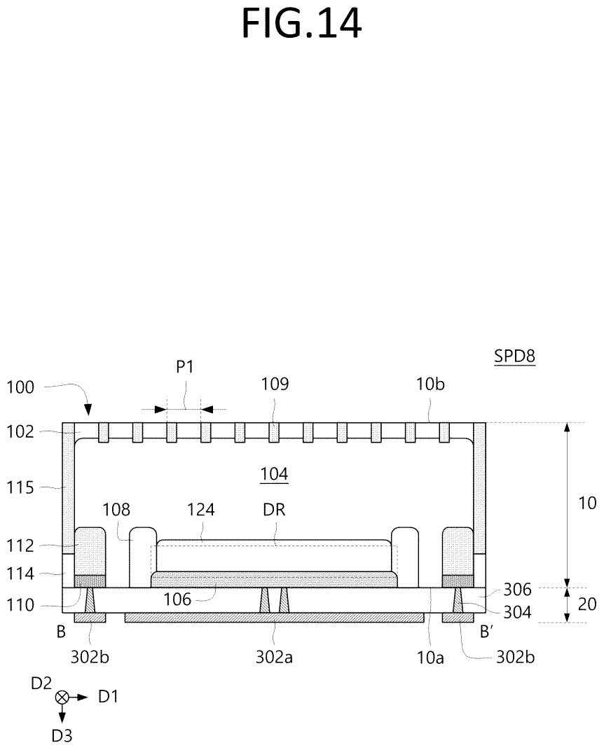

Referring to FIG. 14, a single photon detection device SPD8 may be provided. Unlike what is shown in FIG. 11, the guard ring 108 may extend to a depth deeper than the second well 124. The top surface of the guard ring 108 may be positioned at a depth between the top surface of the second well 124 and the top surface of the first well 104.

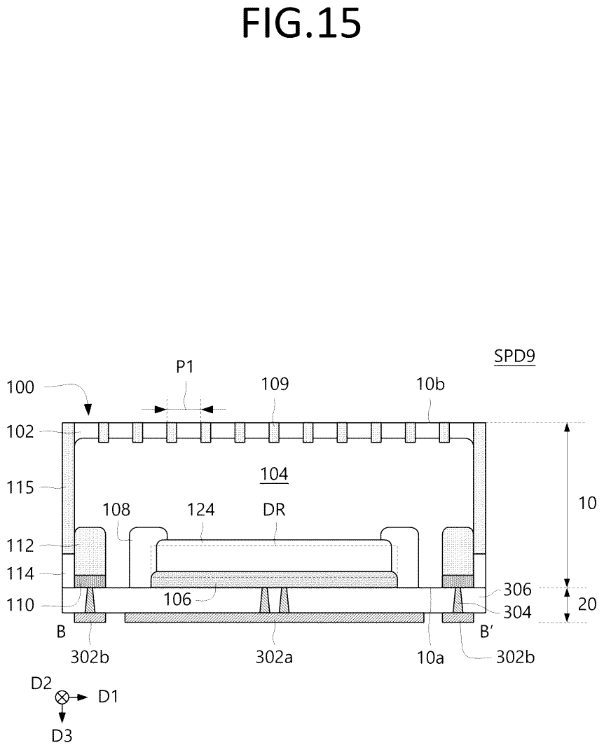

Referring to FIG. 15, a single photon detection device SPD9 may be provided. Unlike what is shown in FIG. 14, the guard ring 108 may extend from a region on the side surface of the second well 124 to a region on the top surface of the second well 124. For example, the guard ring 108 may cover the edge portion of the top surface of the second well 124. The guard ring 108 may contact the top surface of the second well 124.

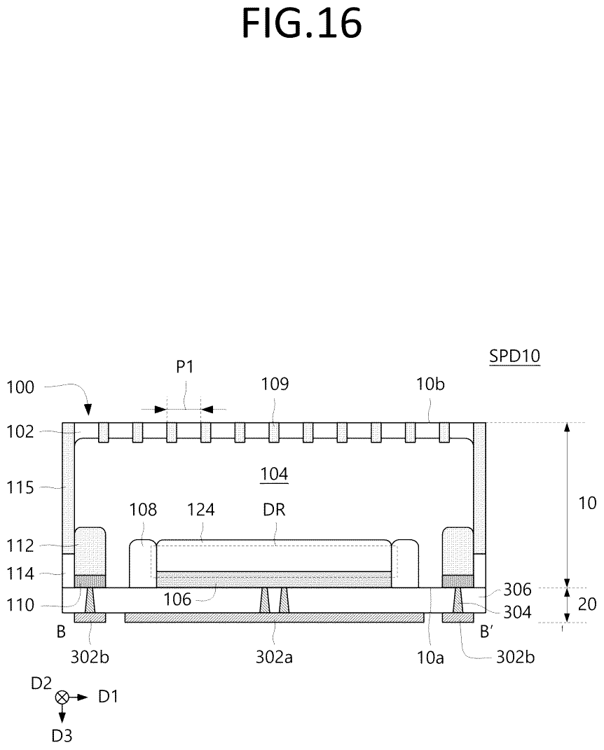

Referring to FIG. 16, a single photon detection device SPD10 may be provided. Unlike what is shown in FIG. 11, the highly doped region 106 and the second well 124 may have substantially the same width. The side surface of the highly doped region 106 may be aligned with the side surface of the second well 124. For example, the side surface of the highly doped region 106 may be coplanar with the side surface of the second well 124.

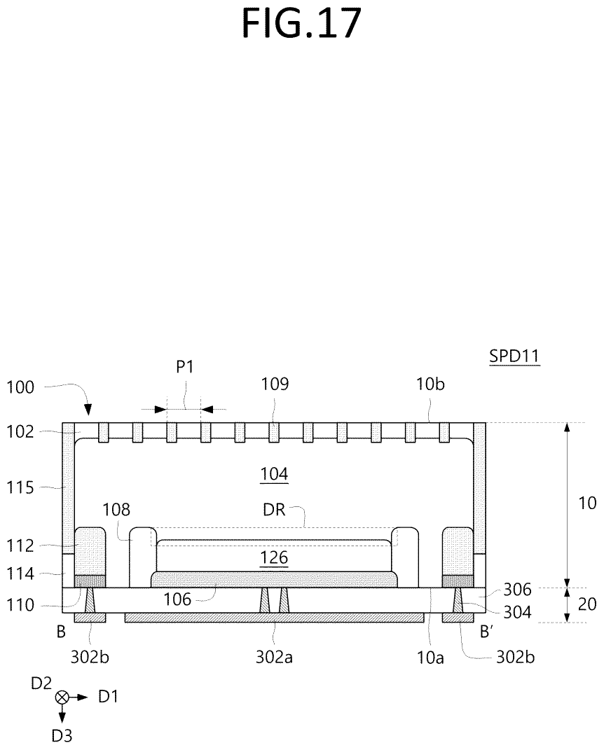

Referring to FIG. 17, a single photon detection device SPD11 may be provided. Unlike what is shown in FIG. 11, the single photon detection device SPD11 may include a third well 126. The third well 126 may be provided between the first well 104 and the highly doped region 106. The third well 126 may space the first well 104 and the highly doped region 106 apart from each other. For example, the third well 126 may directly contact the first well 104 and the highly doped region 106. The third well 126 may be provided in an inner region of the guard ring 108 having a ring shape. From a perspective looking at the front surface 10a, the third well 126 may be surrounded by the guard ring 108. For example, the third well 126 may directly contact the guard ring 108. In exemplary embodiments, the third well 126 may be formed to a depth shallower than the guard ring 108. The top surface of the third well 126 may be positioned closer to the front surface 10a than the top surface of the guard ring 108. The third well 126 may have a second conductivity type. The doping concentration of the third well 126 may be lower than the doping concentration of the highly doped region 106 and higher than the doping concentration of the guard ring 108. For example, the doping concentration of the third well 126 may be 1×10¹⁵ to 5×10¹⁷ cm⁻³. The depletion region DR may be formed at and around the boundary between the third well 126 and the first well 104. The depletion region DR may be formed widely by the third well 126.

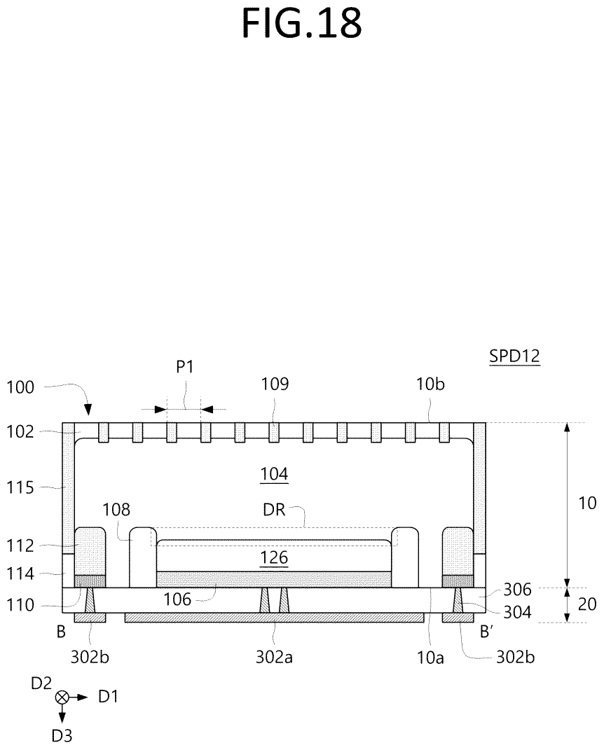

Referring to FIG. 18, a single photon detection device SPD12 may be provided. Unlike what is shown in FIG. 17, the highly doped region 106 and the third well 126 may have substantially the same width. The side surface of the highly doped region 106 may be aligned with the side surface of the third well 126. For example, the side surface of the highly doped region 106 may be coplanar with the side surface of the third well 126.

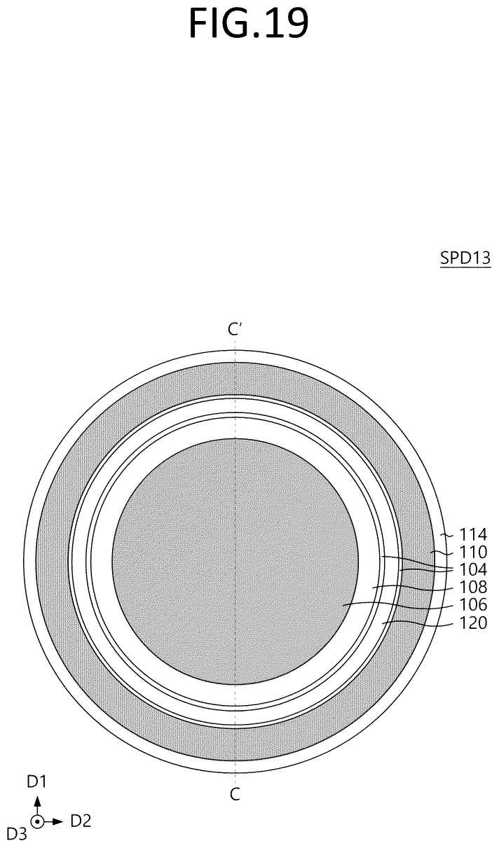

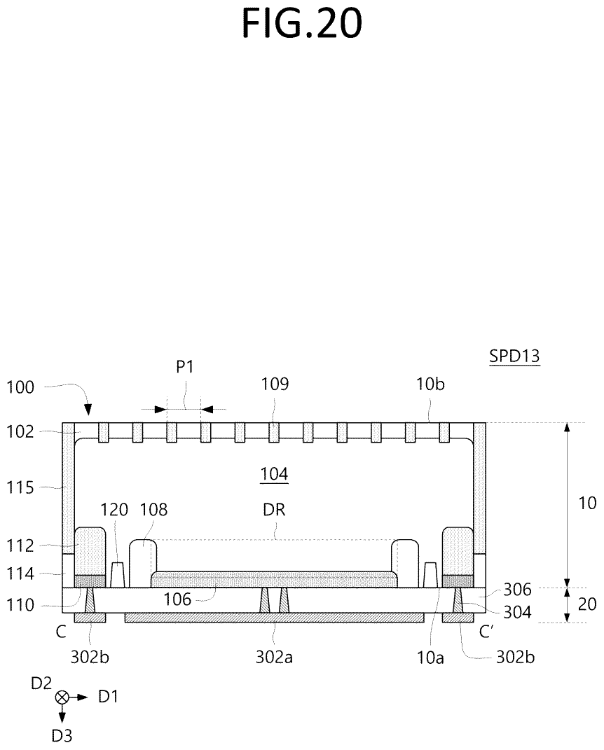

FIG. 19 is a plan view of a single photon detection device according to an exemplary embodiment. FIG. 20 is a cross-sectional view taken along line C-C′ of FIG. 19. For brevity of description, differences from what was described with reference to FIGS. 7 and 8 will be described.

Referring to FIGS. 19 and 20, a single photon detection device SPD13 may be provided. Unlike what is shown in FIGS. 7 and 8, the single photon detection device SPD13 may include a first insulating pattern 120. The first insulating pattern 120 may be provided between the relaxation region 112 and the guard ring 108. The first insulating pattern 120 may be exposed on the front surface 10a. The bottom surface of the first insulating pattern 120 may be exposed between the relaxation region 112 and the guard ring 108. On the front surface 10a, the first insulating pattern 120 may surround the guard ring 108. The first insulating pattern 120 may include an electrically insulating material. For example, the first insulating pattern 120 may include silicon oxide (e.g., SiO₂), silicon nitride (e.g., SiN), silicon oxynitride (e.g., SiON), or combinations thereof. The first insulating pattern 120 may be formed by, for example, a process of filling a recess region formed by etching the semiconductor substrate 100 with an electrically insulating material. For example, the first insulating pattern 120 may be STI. The first insulating pattern 120 may be formed in the substrate 100 before the first well 104. For example, in an ion implantation process for implanting impurities forming the first well 104 into the substrate 100, the first insulating pattern 120 may be configured to lower the ion implantation effect on the region (first well 104) located between the first insulating pattern 120 and the second surface 10b. Compared to the case without the first insulating pattern 120, when the first insulating pattern 120 is present, the doping concentration of one region of the first well 104 located below the first insulating pattern 120 may be lowered. Accordingly, the depletion region DR may be formed widely, and thus the fill factor and efficiency of the single photon detection device SPD13 may be improved.

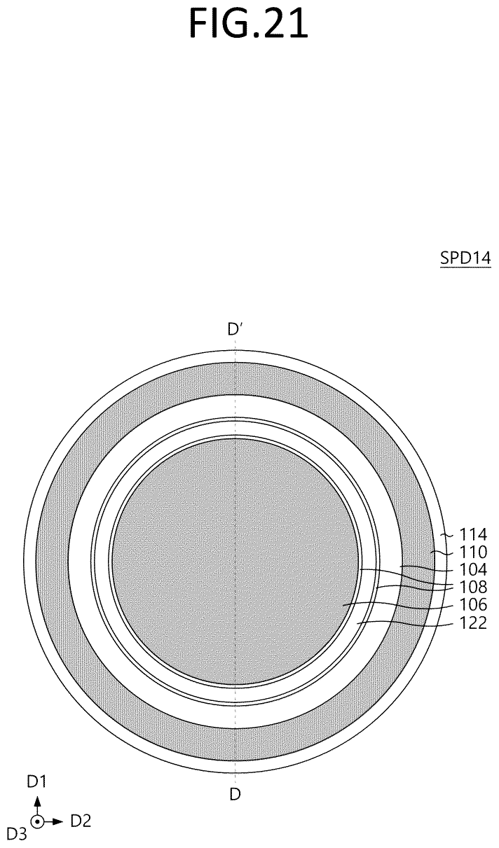

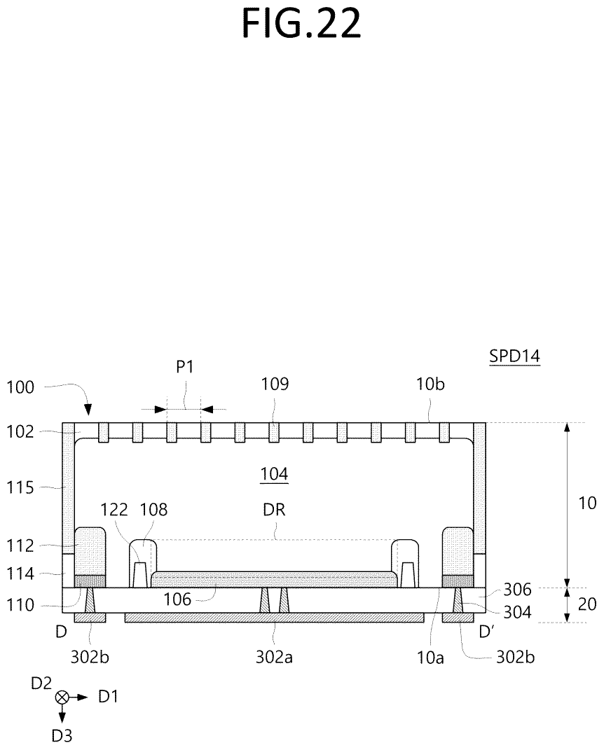

FIG. 21 is a plan view of a single photon detection device according to an exemplary embodiment. FIG. 22 is a cross-sectional view taken along line D-D′ of FIG. 21. For brevity of description, differences from what was described with reference to FIGS. 7 and 8 will be described.

Referring to FIGS. 21 and 22, a single photon detection device SPD14 may be provided. Unlike what is shown in FIGS. 7 and 8, the single photon detection device SPD14 may include a second insulating pattern 122. The second insulating pattern 122 may be provided on the guard ring 108. The second insulating pattern 122 may overlap with the guard ring 108 along the third direction D3. The second insulating pattern 122 may surround the highly doped region 106. For example, the second insulating pattern 122 may have a ring shape extending along the side surface of the highly doped region 106. Although the second insulating pattern 122 is shown as being spaced apart from the highly doped region 106, this is exemplary. In another example, the second insulating pattern 122 may directly contact the highly doped region 106. The second insulating pattern 122 may be formed from the same level as the bottom surface of the highly doped region 106 to a certain depth. The depth of the second insulating pattern 122 may be determined as needed. The second insulating pattern 122 may be inserted into the guard ring 108. For example, the side surfaces and top surface of the second insulating pattern 122 may directly contact the guard ring 108. The bottom surface of the second insulating pattern 122 may be exposed on the bottom surface of the substrate 100.

The second insulating pattern 122 may include an electrically insulating material. For example, the second insulating pattern 122 may include silicon oxide (e.g., SiO₂), silicon nitride (e.g., SiN), silicon oxynitride (e.g., SiON), or combinations thereof. In exemplary embodiments, the second insulating pattern 122 may be STI formed by etching a portion of the semiconductor substrate and then filling the etched region with an electrically insulating material. The second insulating pattern 122 may reduce or prevent premature breakdown by relieving electric field concentration in a portion of the doping region DR. The second insulating pattern 122 may reduce or prevent the influence of surface noise components. The second insulating pattern 122 may be formed in the substrate 100 before the first well 104 and the guard ring 108. The second insulating pattern 122 may reduce the doping concentration of the region located between the second insulating pattern 122 and the second surface 10b. For example, during an ion implantation process for implanting impurities forming the first well 104 and the guard ring 108 into the substrate 100, the second insulating pattern 122 may be configured to lower the ion implantation effect on the region where the first well 104 and the guard ring 108 are formed. Compared to the case without the second insulating pattern 122, when the second insulating pattern 122 is present, the doping concentration of the first well 104 and the guard ring 108 located below the second insulating pattern 122 may be lowered. Accordingly, the depletion region DR may be formed widely, and thus the fill factor and efficiency of the single photon detection device SPD14 may be improved.

In exemplary embodiments, the single photon detection device SPD14 may further include the first insulating pattern 120 described with reference to FIGS. 17 and 18.

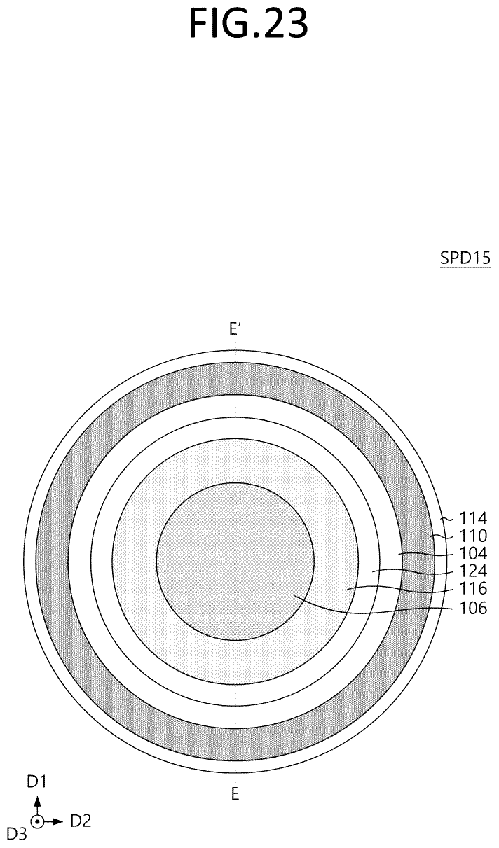

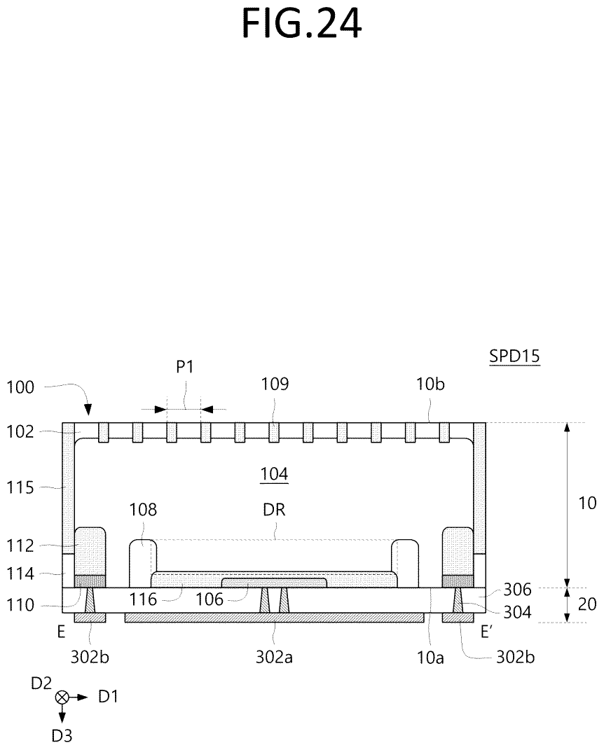

FIG. 23 is a plan view of a single photon detection device according to an exemplary embodiment. FIG. 24 is a cross-sectional view taken along line E-E′ of FIG. 23. For brevity of description, differences from what was described with reference to FIGS. 7 and 8 will be described.

Referring to FIGS. 23 and 24, a single photon detection device SPD15 may be provided. Unlike what was described with reference to FIGS. 7 and 8, the single photon detection device SPD15 may include a lightly doped region 116. The lightly doped region 116 may be provided between the highly doped region 106 and the first well 104. The lightly doped region 116 may contact the top surface and side surface of the highly doped region 106. The lightly doped region 116 may be exposed on the front surface 10a. On the front surface 10a, the lightly doped region 116 may surround the highly doped region 106. The lightly doped region 116 may have a second conductivity type. The lightly doped region 116 may have a lower doping concentration than the highly doped region 106. For example, the doping concentration of the lightly doped region 116 may be 1×10¹⁵ to 1×10¹⁹ cm⁻³. The lightly doped region 116 may contact the first well 104 to form the depletion region DR. The lightly doped region 116 may be configured to reduce or prevent tunneling effects that occur as the size of the semiconductor device becomes smaller. For example, the tunneling effect may be current flow even when no photons are incident on the single photon detection device SPD15. By forming the depletion region DR using the lightly doped region 116, tunneling noise and trap-assisted tunneling noise of the single photon detection device SPD15 may be reduced, and the operating wavelength band of the single photon detection device SPD15 may be widened.

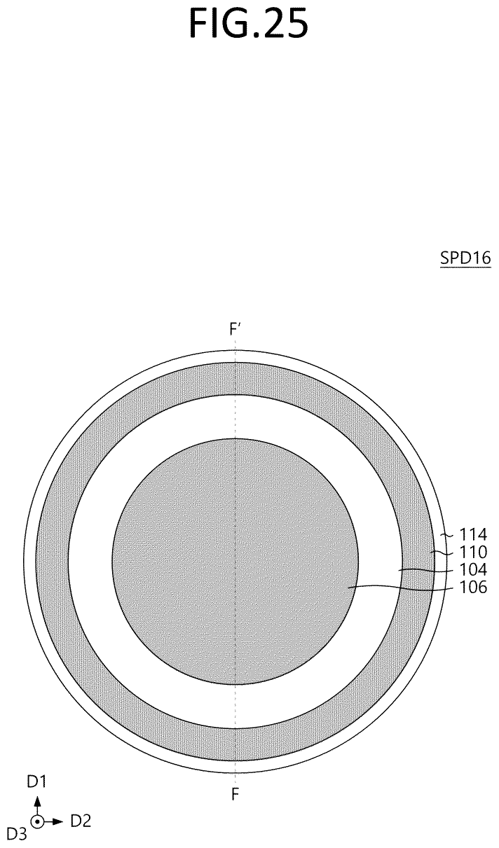

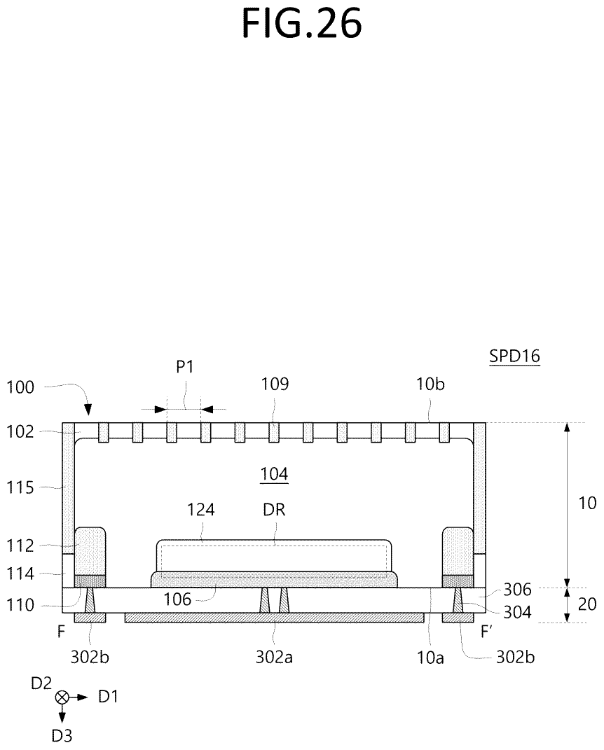

FIG. 25 is a plan view of a single photon detection device according to an exemplary embodiment. FIG. 26 is a cross-sectional view taken along line F-F of FIG. 25. For brevity of description, differences from what was described with reference to FIG. 17 will be described.

Referring to FIGS. 25 and 26, a single photon detection device SPD16 may be provided. Unlike what was described with reference to FIG. 17, the single photon detection device SPD16 may not include the guard ring 108. The highly doped region 106 and the third well 126 may directly contact the first well 104. The region between the highly doped region 106, the third well 126, the relaxation region 112, and the contact region 110 may be filled with the first well 104.

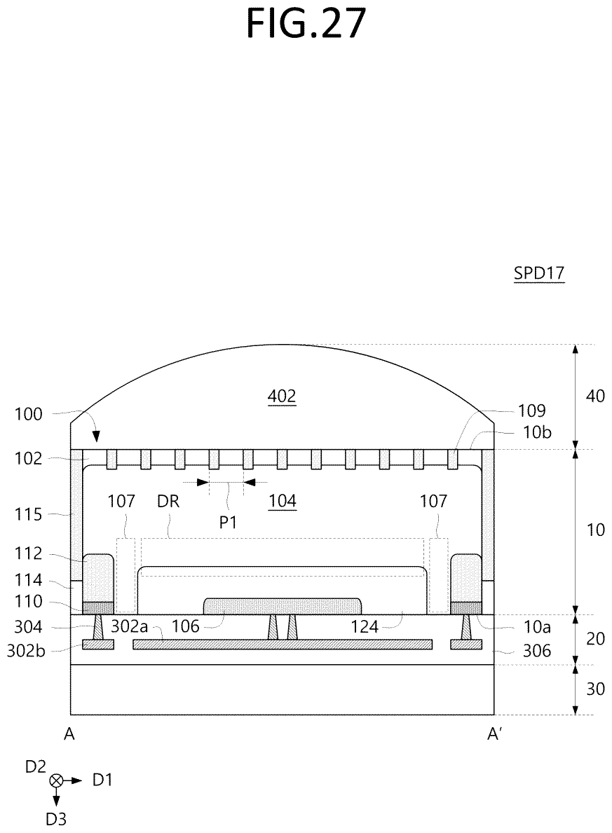

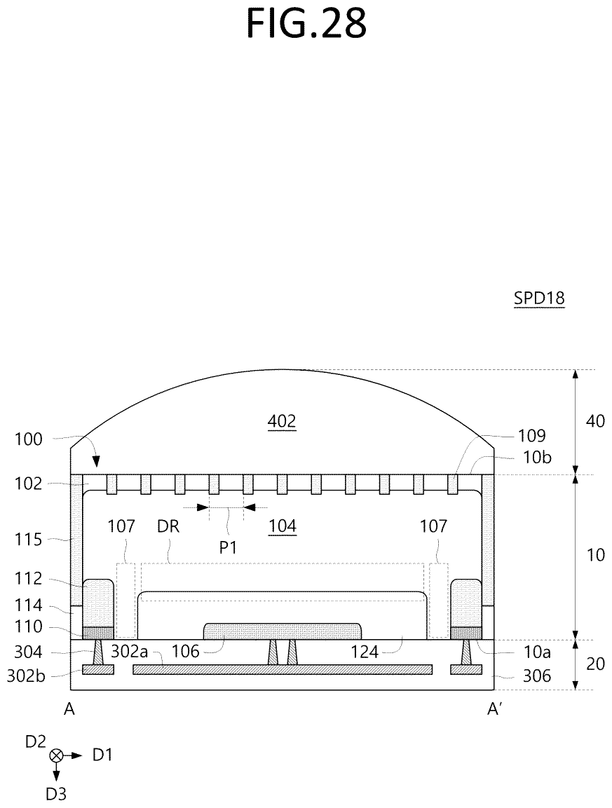

FIGS. 27 and 28 are cross-sectional views corresponding to line A-A′ of FIG. 1. For brevity of description, differences from what was described with reference to FIGS. 1 through 3 will be described.

Referring to FIG. 27, a single photon detection device SPD17 may be provided. Unlike what was described with reference to FIGS. 1 through 3, the single photon detection device SPD17 may include a control layer 30 and an optical element layer 40. The control layer 30 may be provided on the opposite side of the photodetection layer 10 with respect to the connection layer 20. The control layer 30 may include circuits necessary for operation of the photodetection layer 10. For example, the control layer 30 may be a chip on which circuits are formed. The circuits may be implemented by various electronic devices as needed. The circuits may include a quenching resistor (or quenching circuit) and pixel circuits. The quenching resistor (or quenching circuit) may be configured to stop the avalanche effect and allow the photodetection layer 10 to detect another photon. The pixel circuits may include a reset or recharge circuit, memory, an amplification circuit, a counter, a gate circuit, a time-to-digital converter, and the like. The circuits may also include a DC-to-DC converter and other power management integrated circuits. The circuits may transmit signals to the photodetection layer 10 or receive signals from the photodetection layer 10.

The optical element layer 40 may be provided on the back surface 10b. The optical element layer 40 may cover the diffraction patterns 109. The optical element layer 40 may include a lens 402. The lens 402 may focus incident light and transmit it to the photodetection layer 10. For example, the lens 402 may include a microlens, a Fresnel lens, or a metalens. However, the type of lens 402 is not limited and may be determined as needed. In exemplary embodiments, the central axis of the lens 402 may be aligned with the central axis of the photodetection layer 10. The central axis of the lens 402 and the central axis of the photodetection layer 10 may be virtual axes that pass through the center of the lens 402 and the center of the photodetection layer 10, respectively, and are parallel to the stacking direction of the photodetection layer 10 and the lens 402 (i.e., the direction opposite to the third direction D3). In exemplary embodiments, the central axis of the lens 402 may be misaligned with the central axis of the photodetection layer 10. In exemplary embodiments, the width of the lens 402 may be about half the width of the photodetection layer 10. In exemplary embodiments, the lens 402 may be arranged in a 2×2 format. In exemplary embodiments, at least one optical element may be inserted between the lens 402 and the photodetection layer 10. For example, the optical element may be a color filter, a bandpass filter, a metal grid, an air grid, a low refractive index material-based grid, an anti-reflection coating, a 2D nanomaterial layer, or an organic material layer. In exemplary embodiments, the anti-reflection coating may be formed on the lens 402.

Referring to FIG. 28, the single photon detection device SPD18 may include the photodetection layer 10, the connection layer 20, and the optical element layer 40. Unlike what was described with reference to FIG. 27, circuits necessary for operation of the single photon detection device SPD18 may be formed in the photodetection layer 10. For example, the circuits may be provided in a region adjacent to the front surface 10a. For example, the circuits may be provided outside the device isolation pattern 114, that is, on the opposite side of the contact region 110 with respect to the device isolation pattern 114. The circuits may be implemented by various electronic devices as needed. The circuits may include a quenching resistor (or quenching circuit) and pixel circuits. The quenching resistor (or quenching circuit) may be configured to stop the avalanche effect and allow the single photon detection device SPD18 to detect another photon. The pixel circuits may include a reset or recharge circuit, memory, an amplification circuit, a counter, a gate circuit, a time-to-digital converter, and the like. The circuits may also include a DC-to-DC converter and other power management integrated circuits. The circuits may transmit signals to the photodetection layer 10 or receive signals from the photodetection layer 10.

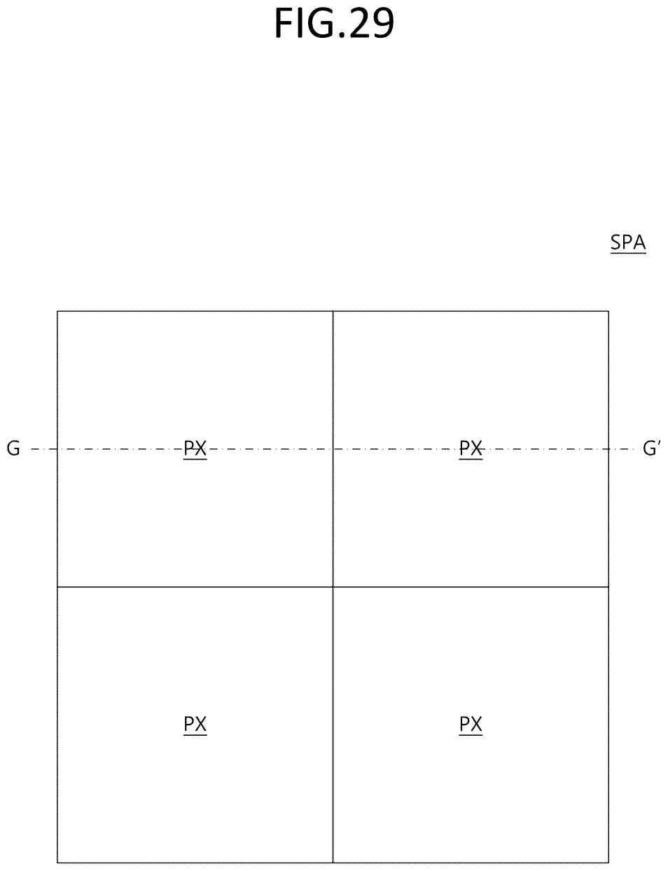

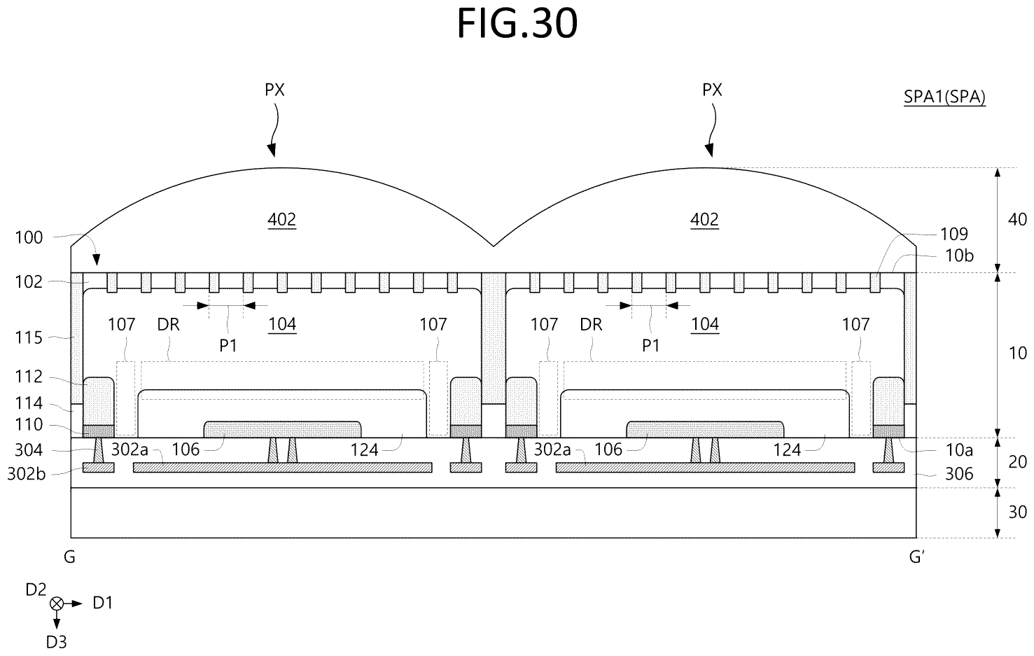

FIG. 29 is a plan view of a single photon detection device array according to an exemplary embodiment. FIG. 30 is a cross-sectional view taken along line G-G′ of FIG. 29. For brevity of description, substantially the same content as described with reference to FIG. 27 may not be described.

Referring to FIGS. 29 and 30, a single photon detection device array SPA1 (SPA) may be provided. The single photon detection device array SPA1 (SPA) may include pixels PX arranged in two dimensions. Each of the pixels PX may include the single photon detection device SPD17 described with reference to FIG. 27. The photodetection layers 10 of the single photon detection devices SPD17 may be connected to form the photodetection layer 10 of the single photon detection device array SPA1 (SPA). The connection layers 20 of the single photon detection devices SPD17 may be connected to form the connection layer 20 of the single photon detection device array SPA1 (SPA). The control layers 30 of the single photon detection devices SPD17 may be connected to form the control layer 30 of the single photon detection device array SPA1 (SPA). The optical element layers 40 of the single photon detection devices SPD17 may be connected to form the optical element layer 40 of the single photon detection device array SPA1 (SPA). In exemplary embodiments, at least one optical element may be inserted between the lens 402 and the photodetection layer 10. For example, the optical element may be a color filter, a bandpass filter, a metal grid, an air grid, a low refractive index material-based grid, an anti-reflection coating, a 2D nanomaterial layer, or an organic material layer. In one example, the anti-reflection coating may be formed on top of the lens 402.

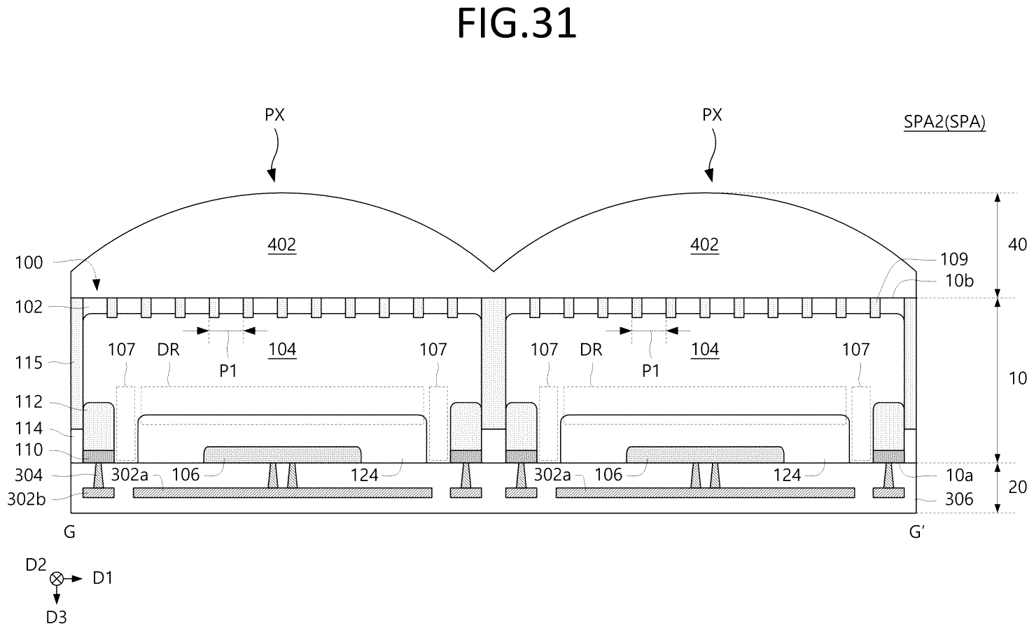

FIG. 31 is a cross-sectional view taken along line G-G′ of FIG. 29. For brevity of description, substantially the same content as described with reference to FIGS. 29 through 30 may not be described.

Referring to FIG. 31, a single photon detection device array SPA2 (SPA) may be provided. The single photon detection device array SPA2 (SPA) may include pixels PX arranged in two dimensions. Each of the pixels PX may include the single photon detection device SPD18 described with reference to FIG. 28. The photodetection layers 10 of the single photon detection devices SPD23 may be connected to form the photodetection layer 10 of the single photon detection device array SPA2 (SPA). The connection layers 20 of the single photon detection devices SPD23 may be connected to form the connection layer 20 of the single photon detection device array SPA2 (SPA). The optical element layers 40 of the single photon detection devices SPD23 may be connected to form the optical element layer 40 of the single photon detection device array SPA2 (SPA). The photodetection layer 10, the connection layer 20, and the optical element layer 40 may be substantially the same as the photodetection layer 10, the connection layer 20, and the optical element layer 40 described with reference to FIGS. 29 and 30, respectively.

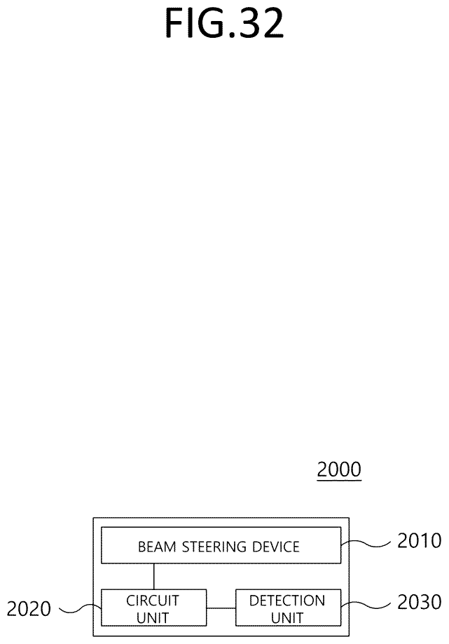

FIG. 32 is a block diagram for explaining an electronic device according to an exemplary embodiment.

Referring to FIG. 32, an electronic device 2000 may be provided. The electronic device 2000 may irradiate light toward a subject (not shown) and detect light reflected by the subject and returned to the electronic device 2000. The electronic device 2000 may include a beam steering device 2010. The beam steering device 2010 may adjust the irradiation direction of light emitted to the outside of the electronic device 2000. The beam steering device 2010 may be a mechanical or non-mechanical (semiconductor-type) beam steering device. The electronic device 2000 may include a light source unit within the beam steering device 2010, or may include a light source unit provided separately from the beam steering device 2010. The beam steering device 2010 may be a scanning-type light emission device. However, the light emission device of the electronic device 2000 is not limited to the beam steering device 2010. In another example, the electronic device 2000 may include a flash-type light emission device instead of or together with the beam steering device 2010. The flash-type light emission device may irradiate light to an area including the entire field of view at once without a scanning process.

Light steered by the beam steering device 2010 may be reflected by the subject and returned to the electronic device 2000. The electronic device 2000 may include a detection unit 2030 for detecting light reflected by the subject. The detection unit 2030 may include a plurality of photodetection elements and may further include other optical members. The plurality of photodetection elements may include any one of the single photon detection devices SPD1 through SPD18 described above. Additionally, the electronic device 2000 may further include a circuit unit 2020 connected to at least one of the beam steering device 2010 and the detection unit 2030. The circuit unit 2020 may include a computation unit that acquires and computes data, and may further include a driving unit and a control unit. Additionally, the circuit unit 2020 may further include a power supply unit and memory.

Although the case where the electronic device 2000 includes the beam steering device 2010 and the detection unit 2030 within one device is shown, the beam steering device 2010 and the detection unit 2030 may not be provided as one device but may be provided separately in separate devices. Additionally, the circuit unit 2020 may be connected to the beam steering device 2010 or the detection unit 2030 not by wire but by wireless communication.

The electronic device 2000 according to the embodiment described above may be applied to various electronic devices. For example, the electronic device 2000 may be applied to a Light Detection And Ranging (LiDAR) device. The LiDAR device may be a phase-shift type or time-of-flight (TOF) type device. Additionally, the single photon detection devices SPD1 through SPD18 according to the embodiment or the electronic device 2000 including them may be mounted in electronic devices such as smartphones, wearable devices (augmented reality and virtual reality glasses-type devices, and the like), Internet of Things (IoT) devices, home appliances, tablet PCs (Personal Computers), PDAs (Personal Digital Assistants), PMPs (Portable Multimedia Players), navigation devices, drones, robots, autonomous vehicles, self-driving cars, Advanced Driver Assistance Systems (ADAS), and the like.

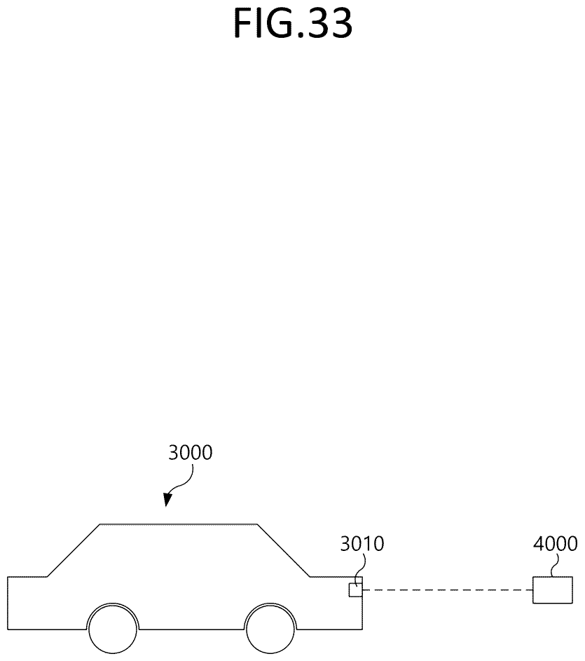

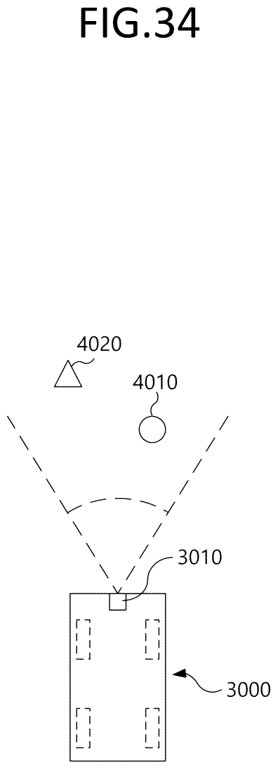

FIGS. 33 and 34 are conceptual diagrams showing a case where a LiDAR device according to an exemplary embodiment is applied to a vehicle.

Referring to FIGS. 33 and 34, a LiDAR device 3010 may be applied to a vehicle 3000. Information about a subject 4000 may be obtained using the LiDAR device 3010 applied to the vehicle. The vehicle 3000 may be an automobile having an autonomous driving function. The LiDAR device 3010 may detect objects or people in the direction the vehicle 3000 is traveling, that is, the subject 4000. The LiDAR device 3010 may measure the distance to the subject 4000 using information such as the time difference between the transmission signal and the detection signal. The LiDAR device 3010 may obtain information about a nearby subject 4010 and a distant subject 4020 within the scan range. The LiDAR device 3010 may include the electronic device 2000 described with reference to FIG. 32. Although the LiDAR device 3010 is shown as being disposed in front of the vehicle 3000 to detect the subject 4000 in the direction the vehicle 3000 is traveling, this is not limiting. In another example, the LiDAR device 3010 may be disposed at multiple positions on the vehicle 3000 so as to detect all subjects 4000 around the vehicle 3000. For example, four LiDAR devices 3010 may be respectively disposed at the front, rear, and both sides of the vehicle 3000. In yet another example, the LiDAR device 3010 may be disposed on the roof of the vehicle 3000 and rotate to detect all subjects 4000 around the vehicle 3000.

According to the present disclosure, a single photon detection device and an electronic device having improved light absorption efficiency may be provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A single photon detection device comprising:
a photodetection layer including a first surface and a second surface positioned opposite to each other,
wherein the photodetection layer comprises:
a first well having a first conductivity type;
diffraction patterns positioned between the second surface and the first well, the diffraction patterns configured to receive incident light and diffract the incident light such that first-order diffracted light has a highest diffraction efficiency in a red or near-infrared wavelength band;
a highly doped region positioned between the first surface and the first well and having a second conductivity type different from the first conductivity type; and
a contact region electrically connected to the first well and having the first conductivity type.

2. The single photon detection device of claim 1, wherein the diffraction patterns are arranged to have a pitch of 0.4 micrometers (μm) to 0.7 micrometers (μm).

3. The single photon detection device of claim 1, wherein the diffraction patterns are exposed on the second surface.

4. The single photon detection device of claim 3, wherein the diffraction patterns contact the first well.

5. The single photon detection device of claim 1, wherein the diffraction patterns have a + shape, an x shape, and a shape in which + and x are overlapped.

6. The single photon detection device of claim 1, wherein the photodetection layer further comprises:
a guard ring provided between the highly doped region and the contact region, having the second conductivity type, and having a doping concentration lower than the highly doped region.

7. The single photon detection device of claim 1, wherein the photodetection layer further comprises:
a relaxation region provided on the contact region, having the first conductivity type, and having a doping concentration lower than the contact region.

8. The single photon detection device of claim 1, wherein the photodetection layer further comprises: a lightly doped region provided on the highly doped region.

9. The single photon detection device of claim 8, wherein the lightly doped region covers side surfaces and a top surface of the highly doped region.

10. The single photon detection device of claim 1, further comprising: a connection layer provided on the first surface,
wherein the connection layer comprises:
an output pattern electrically connected to the highly doped region;
a bias pattern electrically connected to the contact region; and
vertical connection parts provided between the output pattern and the highly doped region and between the bias pattern and the contact region.

11. The single photon detection device of claim 10, wherein the output pattern has a width wider than the highly doped region.

12. The single photon detection device of claim 1, wherein the photodetection layer further comprises a second well provided between the highly doped region and the first well and having the first conductivity type.

13. The single photon detection device of claim 1, further comprising: a third well provided between the highly doped region and the first well, having the second conductivity type, and having a doping concentration lower than the highly doped region.

14. The single photon detection device of claim 1, wherein the photodetection layer further comprises:
a device isolation pattern surrounding the contact region; and
a vertical isolation pattern provided between the device isolation pattern and the second surface.

15. An electronic device comprising a light emission device and a single photon detection device for detecting incident light that is emitted from the light emission device, reflected by a subject, and returned, the electronic device being configured to measure a distance to the subject using time difference information between a transmission signal of the light emission device and a detection signal of the single photon detection device,
wherein the single photon detection device comprises:
a photodetection layer including a first surface and a second surface positioned opposite to each other,
wherein the photodetection layer comprises: a first well having a first conductivity type, diffraction patterns positioned between the second surface and the first well and configured to receive incident light and diffract the incident light such that first-order diffracted light has a highest diffraction efficiency in a red or near-infrared wavelength band, a highly doped region positioned between the first surface and the first well and having a second conductivity type different from the first conductivity type, and a contact region electrically connected to the first well and having the first conductivity type.

16. The electronic device of claim 15, wherein the diffraction patterns are arranged to have a pitch of 0.4 micrometers (μm) to 0.7 micrometers (μm).

17. The electronic device of claim 15, wherein the diffraction patterns are exposed on the second surface and contact the first well.

18. The electronic device of claim 15, wherein the single photon detection device further comprises:
a connection layer provided on the first surface,
wherein the connection layer comprises:
an output pattern electrically connected to the highly doped region;
a bias pattern electrically connected to the contact region; and
vertical connection parts provided between the output pattern and the highly doped region and between the bias pattern and the contact region.

19. An electronic device of claim 18, wherein the output pattern has a width wider than the highly doped region.

20. The electronic device of claim 15, wherein the photodetection layer further comprises: a device isolation pattern surrounding the contact region; and a vertical isolation pattern provided between the device isolation pattern and the second surface.
